(19) United States
(12) Patent Application Publication
(10) Pub. No.: US 2023/0296980 A1
(43) Pub. Date: Sep. 21, 2023

(54) RESIST MATERIAL AND PATTERN FORMING METHOD

(71) Applicant: SHIN-ETSU CHEMICAL CO., LTD., Tokyo (JP)

(72) Inventors: Yutaro OTOMO, Joetsu-shi (JP); Tomohiro Kobayashi, Joetsu-shi (JP); Gentaro Hida, Joetsu-shi (JP); Kousuke Ohyama, Joetsu-shi (JP); Masayoshi Sagehashi, Joetsu-shi (JP); Masahiro Fukushima, Joetsu-shi (JP)

(73) Assignee: SHIN-ETSU CHEMICAL CO., LTD., Tokyo (JP)

(21) Appl. No.: 18/180,936

(22) Filed: Mar. 9, 2023

(30) Foreign Application Priority Data
Mar. 17, 2022 (JP) 2022-42868

(51) Int. Cl. G03F 7/039; G03F 7/38

(52) U.S. Cl. CPC G03F 7/0392; G03F 7/38

(57) ABSTRACT

An object of the present invention is to provide a resist material and a pattern forming method with which the edge roughness and dimension variation become small, superior resolution can be obtained, pattern shape becomes preferable after exposure, and further preferable storage stability can be obtained. A resist material including (Ia) a polymer containing a repeating unit (A) including a hydroxyl group or a carboxy group; (II) a crosslinking agent having a structure represented by the following formula (1); (III) a quencher having a structure represented by the following formula (2); (IV) an organic solvent; and (V) a component which is decomposed by irradiation of an active ray or a radiant ray to generate an acid,

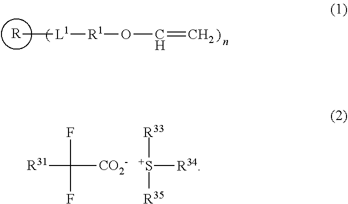

### TECHNICAL FIELD

The present invention relates to a resist material and a pattern forming method.

### BACKGROUND ART

With higher integration and speed up of LSI, miniaturization of pattern rule has been proceeding rapidly. This is because high speed communication of 5G and artificial intelligence (AI) have become widely available, and a high-performance device is required for processing them. Cutting-edge technologies for miniaturization include mass production of 5 nm node devices by using extreme ultraviolet (EUV) lithography with a wavelength of 13.5 nm. Furthermore, in 3 nm node devices of the next generation, and 2 nm node devices of the more advanced generation, use of EUV lithography is under consideration.

In lithography using a DUV light source, i.e., KrF and ArF excimer laser, chemically amplified resists realized high-sensitivity and high-resolution lithography, and has led miniaturization as a main resist used for actual production processes. The chemically amplified resist changes the solubility to a developing solution by using an acid generated from a photosensitizer by exposure as a catalyst to cause a reaction of a base polymer resin.

Also in the next generation lithography such as EUV, the chemically amplified resist has been widely considered, and is currently in commercial use. On the other hand, along with miniaturization, requirement for improvement in resist performance becomes increasingly higher. Particularly, variation in resist pattern dimensions (LER: Line Edge Roughness) affects variation in pattern dimensions after substrate processing, and eventually can affect operation stability of the devices. Therefore, it is required to suppress LER to the utmost limit.

As a factor of LER in the chemically amplified resist, the property of a dissolution rate change curve (dissolution contrast) relative to the exposure amount, acid diffusion length, compatibility of the mixed composition, and the like, are exemplified. In addition, the effects of the chain length, molecular size, and molecular weight of polymer resins have recently been noticed. It is supposedly effective to decrease the molecular weight of polymers for decreasing a dissolution unit in development for reduction of LER.

However, along with decrease in the molecular weight of base polymers, problems such as pattern collapse due to lowering of strength, promotion of acid diffusion along with lowering of glass transition point, and lowering of resolution along with increase in the solubility to a developing solution in an unexposed part may possibly occur. To solve these problems, an attempt has been made to crosslink polymer chains by a crosslinking group having acid degradability. By crosslinking, the molecular weight can be increased in advance, and also crosslinking in an exposed part can be decomposed by an acid generated in exposure. Patent Document 1 discloses a crosslinking polymer obtained by reacting a unit containing a carboxy group or a hydroxyl group with a divinyl ether unit.

On the other hand, crosslinking polymers generated by crosslinking of polymer chains have a significantly high molecular weight so that aggregation of polymers is generated after long-term storage as a resist solution. Thus, a problem of increased number of defects is caused.

Patent Document 2 discloses a resist material containing a polymer having a reactive site and a monomer crosslinking agent.

However, there is a problem that a crosslinking reaction between the crosslinking agent and the polymer does not proceed sufficiently in a baking process after application of the resist material onto a substrate, and remaining monomeric components negatively affect the lithography performance. Further, there is also a problem that crosslinking structures are easily decomposed when acids generated in the exposed part by the action of a photoacid generator diffuse into the unexposed part.

### CITATION LIST

### Patent Literature

Patent Document 1: JP 5562651 B
Patent Document 2: International Publication WO 2018/079449 A1

### SUMMARY OF INVENTION

### Technical Problem

A resist containing a compound having a vinyl ether group as a crosslinking agent forms an acetal structure by an addition reaction to a carboxy group or a hydroxyl group. Meanwhile, the generated acetal structure is easily decomposed by an action of a strong acid component generated from a photoacid generator. Therefore, it becomes a resist film with low molecular weight in an exposed part and with high molecular weight in an unexposed part, so that dissolution contrast can be enhanced.

However, in a conventional crosslinking agent-containing resist, crosslinking reaction does not proceed sufficiently in a baking process for a short time, and the crosslinking agent remains unreacted. In addition, since the acetal structure is highly decomposable, it is easily decomposed to generate a monomer component by diffusion of the strong acid components generated in the exposed part. Such a component has problems of promoting diffusion of acids generated by exposure to deteriorate lithography performance due to having an effect like a plasticizer in the resist film to lower the glass transition point of the film. Moreover, addition of an acid to a resist solution for the purpose of promoting the crosslinking reaction has problems in view of storage stability for causing progress of undesired crosslinking reaction during storage of the solution.

The present invention has been made in view of the above circumstances. An object of the present invention is to provide a resist material and a pattern forming method with which the edge roughness and dimension variation become small, superior resolution can be obtained, the pattern shape becomes preferable after exposure, and further preferable storage stability can be obtained.

### Solution to Problem

To solve the above problem, the present invention provides a resist material comprising:
(Ia) a polymer containing a repeating unit (A) including a hydroxyl group or a carboxy group;
(II) a crosslinking agent having a structure represented by the following formula (1);
(III) a quencher having a structure represented by the following formula (2);
(IV) an organic solvent; and
(V) a component which is decomposed by irradiation of an active ray or a radiant ray to generate an acid,

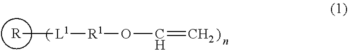

wherein R represents an n-valent organic group which may have a substituent; L¹ represents a linking group selected from a single bond, an ester bond, and an ether bond; R¹ represents a single bond or a divalent organic group; and n is an integer of 1 to 4,

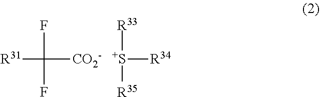

wherein R³¹ represents a monovalent organic group which may have a substituent; R³³ to R³⁵ each independently represent a monovalent hydrocarbon group which has 1 to 20 carbon atoms and may contain a hetero atom; and either two of R³³, R³⁴, and R³⁵ may bond to each other to form a ring with the sulfur atom to which they bond.

With such a resist material, it is possible to provide a resist material with which the edge roughness and dimension variation become small, superior resolution can be obtained, pattern shape becomes preferable after exposure, and further preferable storage stability can be obtained.

Further, the present invention provides a resist material comprising:
(Ib) a polymer containing a repeating unit (A) including a hydroxyl group or a carboxy group, and a repeating unit (C) having a structural site which is decomposed by irradiation of an active ray or a radiant ray to generate an acid;
(II) a crosslinking agent having a structure represented by the following formula (1);
(III) a quencher having a structure represented by the following formula (2); and
(IV) an organic solvent,

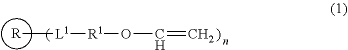

wherein R represents an n-valent organic group which may have a substituent; L¹ represents a linking group selected from a single bond, an ester bond, and an ether bond; R¹ represents a single bond or a divalent organic group; and n is an integer of 1 to 4,

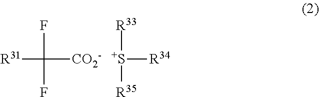

wherein R³¹ represents a monovalent organic group which may have a substituent; R³³ to R³⁵ each independently represent a monovalent hydrocarbon group which has 1 to 20 carbon atoms and may contain a hetero atom; and either two of R³³, R³⁴, and R³⁵ may bond to each other to form a ring with the sulfur atom to which they bond.

With such a resist material, it is possible to provide a resist material with which the edge roughness and dimension variation after exposure become small, superior resolution can be obtained, pattern shape becomes preferable after exposure, and further preferable storage stability can be obtained.

The repeating unit (C) contained in the polymer is preferably represented by the following formula (c),

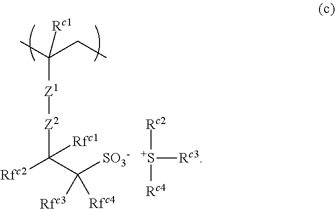

wherein R^{c1} represents a hydrogen atom or a methyl group; Z¹ represents a single bond or an ester bond; Z² represents a single bond or a divalent organic group having 1 to 25 carbon atoms, and may include one or more of an ester bond, an ether bond, a lactone ring, an amide bond, a sultone ring, and an iodine atom; Rf^{c1} to Rf^{c4} each independently represent a hydrogen atom, fluorine atom, or a trifluoromethyl group, and at least one of Rf^{c1} to Rf^{c4} is a fluorine atom or a trifluoromethyl group; and R^{c2} to R^{c4} each independently represent a monovalent hydrocarbon group which has 1 to 20 carbon atoms and may contain a hetero atom; and either two of R^{c2}, R^{c3}, and R^{c4} may bond to each other to form a ring with the sulfur atom to which they bond.

With such a resist material, it is possible to provide a resist material having good solubility to an alkaline developing solution.

The resist material preferably further comprises (V) a component which is decomposed by irradiation of an active ray or a radiant ray to generate an acid.

With such a resist material, it is possible to improve the dissolution contrast with an unexposed part.

The repeating unit (A) contained in the polymer is preferably represented by the following formula (a1) and/or (a2),

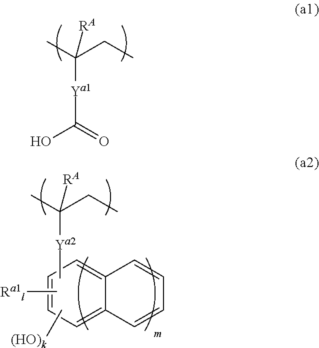

wherein R^{A}s each independently represent a hydrogen atom or a methyl group; Y^{a1} each independently represents a single bond, or a divalent linking group having 1 to 15 carbon atoms and including at least one or more of a phenylene group, a naphthylene group, an ester bond, an ether bond, a lactone ring, an amide group, and a hetero atom; Y^{a2} each independently represents a single bond, or a divalent linking group having 1 to 12 carbon atoms and including at least one or more of a phenylene group, a naphthylene group, an ester bond, an ether bond, a lactone ring, an amide group, and a hetero atom; R^{a1} represents a hydrogen atom, a fluorine atom, or an alkyl group; R^{a1} and Y^{a2} may bond to each other to form a ring; and k is an integer of 1 or 2, l is an integer of 0 to 4, and l≤k+1≤5; and m is 0 or 1.

With such a resist material, it is possible to suppress diffusion of an acid generated in an exposed part by the action of a photoacid generator.

R³¹ in the formula (2) preferably comprises an iodine atom.

With such a resist material, it is possible to suppress diffusion of an acid generated in an exposed part by the action of a photoacid generator.

R in the formula (1) preferably comprises an aromatic hydrocarbon group.

With such a resist material, it is possible to improve the contrast between an exposed part and unexposed part.

Further, the present invention provides a pattern forming method which comprises
(i) a step of forming a resist film by applying the resist material onto a substrate to form a resist film;
(ii) a step of exposing the resist film to a high energy ray; and
(iii) a step of developing the exposed resist film with a developing solution.

With such a pattern forming method, a pattern with small edge roughness and dimension variation, having excellent resolution, and also having a preferable pattern shape after exposure can be obtained.

Further, the step (i) preferably comprises a step of prebaking the resist film at 130° C. or more.

With such a pattern forming method, a crosslinking reaction can be efficiently proceeded by a crosslinking agent.

### Advantageous Effects of Invention

The resist material of the present invention contains a polymer including a reactive group, a vinyl ether crosslinking agent, and additionally a quencher of weak acid sulfonium salt type. The conjugate acid of this weakly acidic anion has a weaker acidity than a strong acid component generated from a photoacid generator, and performs salt exchange with a strong acid generated by exposure to form a weak acid and a strong acid-sulfonium salt. Thus, it functions as a quencher suppressing decomposition of an acetal structure or acid-labile group by substituting the strong acid generated in the exposed part with a weak acid. On the other hand, in a region which is sufficiently exposed, a sulfonium cation after the salt exchange is also decomposed to generate a strong acid. Therefore, the crosslinking structure rapidly collapses without inhibiting decomposition of acetal, so that the molecular weight can be reduced.

By the effect of the above quencher component, while the resist material of the present invention is in a neutral environment in a solution state, it is in a weakly acidic environment at a minute exposed region. As a result of intensive investigation, in the resist material of the present invention, it was confirmed that an alkanesulfonate or the like makes the acidity high and induces decomposition of an acetal structure even in the minute exposed region; meanwhile, a carboxylate can suppress decomposition of acetal. Further, it was surprisingly found that in a system using a quencher having increased acidity by giving fluorine at the α-position of a carboxylic acid, decomposition of acetal does not occur in the minute exposed region, and rather an acidity suitable for catalyzing a crosslinking reaction of a vinyl ether group with a hydroxyl and carboxy groups is held.

That is, the resist material of the present invention containing a specific quencher component and a vinyl ether crosslinking agent allows the crosslinking reaction of polymer chains to be efficiently proceeded by the above effect, and has high effect of suppressing acid diffusion. Therefore, the pattern shape, roughness and resolution after exposure are excellent, and also the storage stability is preferable. The resist material of the present invention has these excellent characteristics, and thus has extremely high practicality. Particularly, it is very useful as a material for forming a fine pattern of photomasks for VLSI fabrication or by EB drawing, and a pattern forming material for EB or EUV lithography. The positive resist material of the present invention can be applied to, for example, not only lithography in semiconductor circuit formation, but also formation of a mask circuit pattern, micromachine, and circuit formation of a thin film magnetic head.

### BRIEF DESCRIPTION OF DRAWINGS

FIG. 1 is a graph showing comparison of contrast between Examples and Comparative Examples of the present invention.

### DESCRIPTION OF EMBODIMENTS

As mentioned above, there has been a demand for development of a resist material with which the edge roughness and dimension variation become small, superior resolution can be obtained, pattern shape becomes preferable after exposure, and further preferable storage stability can be obtained.

The present inventors made intensive investigation to solve the above problems, and as a result, enabled pattern forming with small LER and excellent resolution by a resist containing a polymer compound having a specific functional group, a specific vinyl ether crosslinking agent, and a specific carboxylate type quencher component, and also overcame the problem of storage stability. Thereby, the present invention was completed.

That is, the first aspect of the present invention is a resist material comprising:
(Ia) a polymer containing a repeating unit (A) including a hydroxyl group or a carboxy group;
(II) a crosslinking agent having a structure represented by the following formula (1);
(III) a quencher having a structure represented by the following formula (2);
(IV) an organic solvent; and
(V) a component which is decomposed by irradiation of an active ray or a radiant ray to generate an acid,

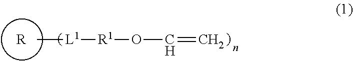

wherein R represents an n-valent organic group which may have a substituent; L¹ represents a linking group selected from a single bond, an ester bond, and an ether bond; R¹ represents a single bond or a divalent organic group; and n is an integer of 1 to 4,

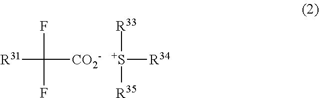

wherein R³¹ represents a monovalent organic group which may have a substituent; R³³ to R³⁵ each independently represent a monovalent hydrocarbon group which has 1 to 20 carbon atoms and may contain a hetero atom; and either two of R³³, R³⁴, and R³⁵ may bond to each other to form a ring with the sulfur atom to which they bond.

Further, the second aspect of the present invention is a resist material comprising:
(Ib) a polymer containing a repeating unit (A) including a hydroxyl group or a carboxy group, and a repeating unit (C) having a structural site which is decomposed by irradiation of an active ray or a radiant ray to generate an acid;
(II) a crosslinking agent having a structure represented by the following formula (1);
(III) a quencher having a structure represented by the following formula (2); and
(IV) an organic solvent,

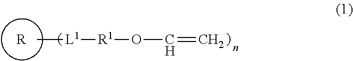

wherein R represents an n-valent organic group which may have a substituent; L¹ represents a linking group selected from a single bond, an ester bond, and an ether bond; R¹ represents a single bond or a divalent organic group; and n is an integer of 1 to 4,

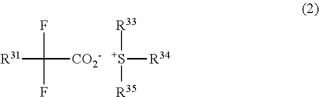

wherein R³¹ represents a monovalent organic group which may have a substituent; R³³ to R³⁵ each independently represent a monovalent hydrocarbon group which has 1 to 20 carbon atoms and may contain a hetero atom; and either two of R³³, R³⁴, and R³⁵ may bond to each other to form a ring with the sulfur atom to which they bond.

Hereinafter, the present invention will be described in detail. However, the present invention is not limited thereto.

### First Aspect

The first aspect of the present invention is a resist material containing the above components (Ia), (II), (III), (IV), and (V). Hereinafter, each component is described in detail.

### Base Polymer (Ia)

The base polymer (P) according to the present invention includes a polymer containing the repeating unit (A) including a hydroxyl group or a carboxyl group. Since the repeating unit (A) functions as a reaction site with the below-mentioned crosslinking agent (II) to form a polymer on a substrate, diffusion of the acid generated in an exposed part by an action of a photoacid generator can be suppressed.

The repeating unit (A) is preferably one represented by the following formula (a1) or (a2).

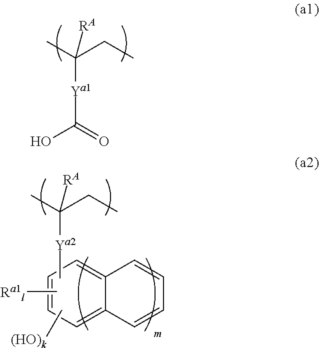

In the formulas (a1) and (a2), R^{A} represents a hydrogen atom or a methyl group.

In the formula (a1), Y^{a1} each independently represents a single bond, or a divalent linking group having 1 to 15 carbon atoms and including at least one or more of a phenylene group, a naphthylene group, an ester bond, an ether bond, a lactone ring, an amide group, and a hetero atom.

In the formula (a2), Y^{a2} each independently represents a single bond, or a divalent linking group having 1 to 12 carbon atoms and including at least one or more of a phenylene group, a naphthylene group, an ester bond, an ether bond, a lactone ring, an amide group, and a hetero atom.

In the formula (a2), R^{a1} represents a hydrogen atom, a fluorine atom, or an alkyl group, and R^{a1} and Y^{a2} may bond to each other to form a ring.

In the formula (a2), k is 1 or 2. l is an integer of 0 to 4, provided that l≤k+1≤5. m is an integer of 0 or 1.

Examples of a monomer giving the repeating unit (a1) include, but not limited to, those shown below.

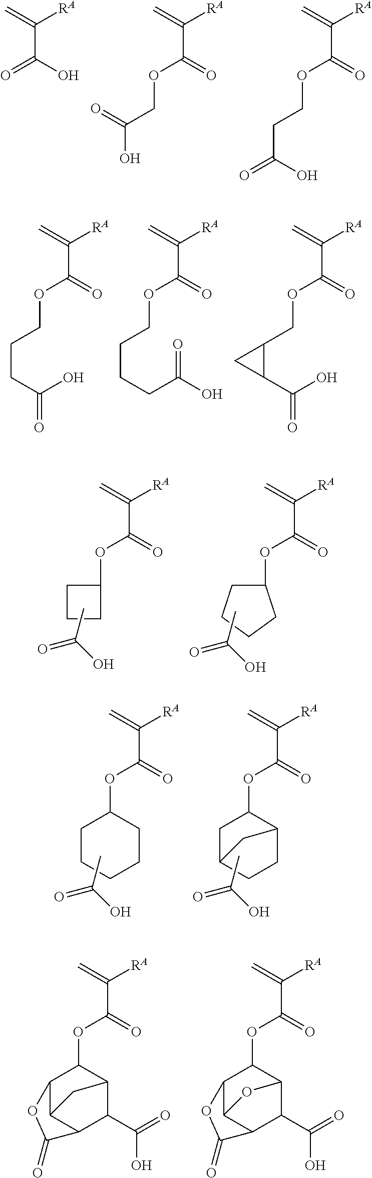

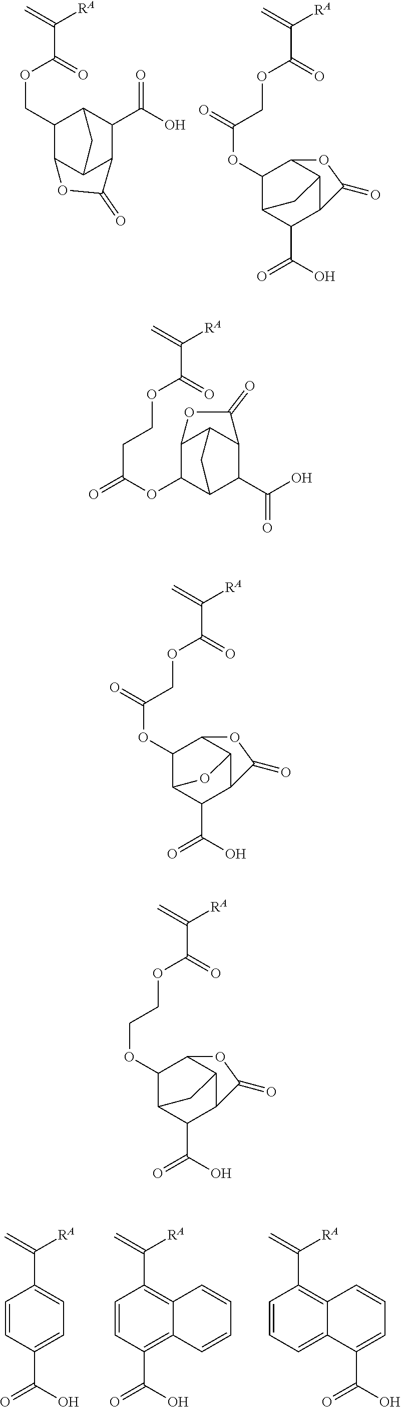

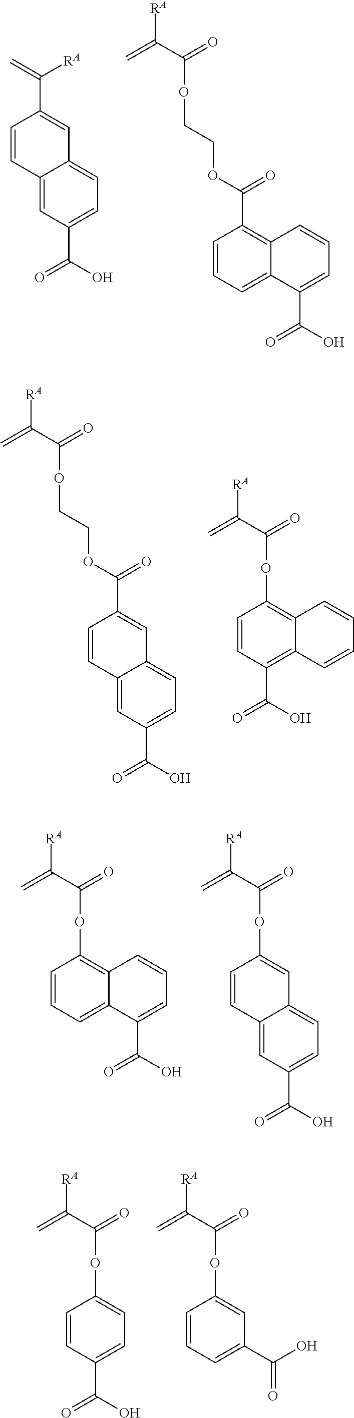

Examples of a monomer giving the repeating unit (a2) include, but not limited to, those shown below.

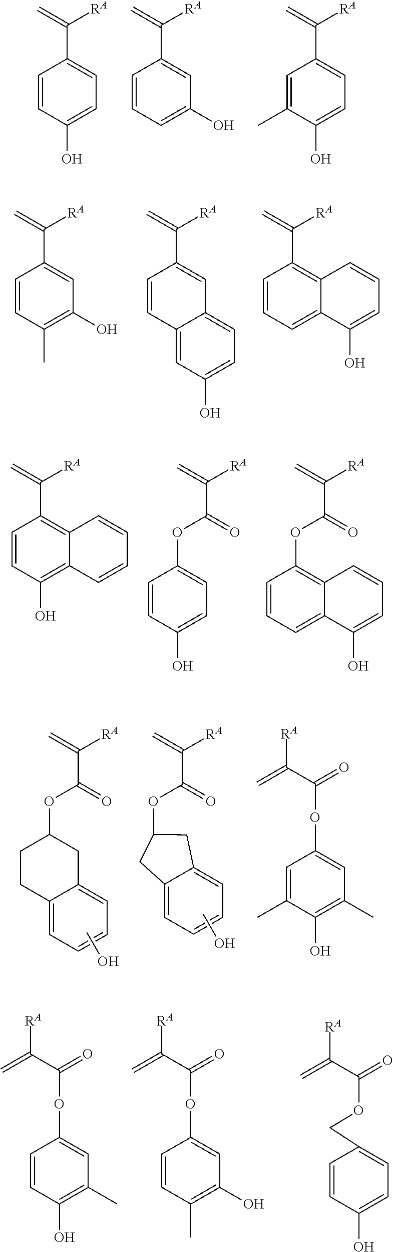

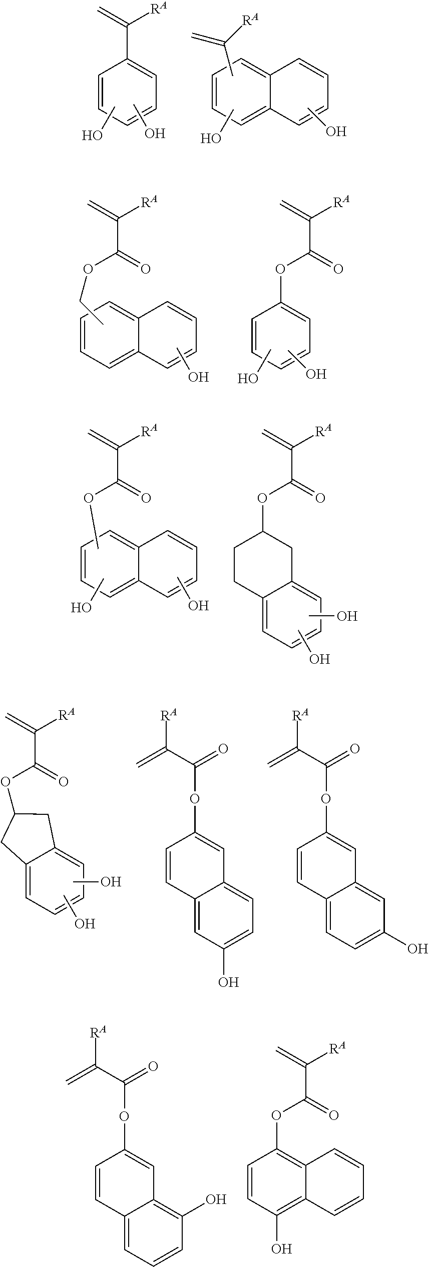

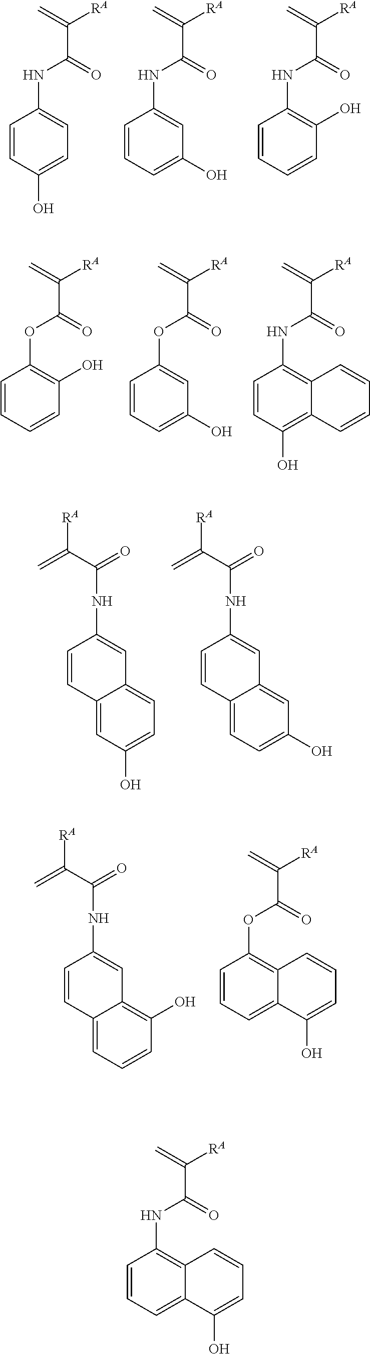

The content of the repeating unit (A) in the base polymer (P) is preferably 5 mol % or more, and more preferably 10 mol % or more and 80 mol % or less.

Repeating units other than the repeating units (a1) and (a2) may also be used as the repeating unit (A).

The base polymer (P) preferably contains a repeating unit (B) obtained by substituting the hydrogen atom of a carboxy group in the repeating unit (A) with an acid-labile group. Examples of a primary means for converting the solubility of a resist film to a developing solution include changing the molecular weight and changing the polarity. By the function of the crosslinking agent (II), an effect of changing the molecular weight can be obtained, and an effect of changing the polarity can also be obtained by the repeating unit (B), so that the contrast can be significantly improved.

The repeating unit (B) is preferably one represented by the following formula (b).

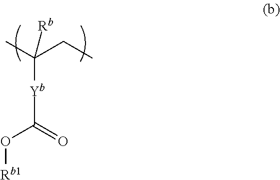

In the formula (b), Rb represents a hydrogen atom or a methyl group. Y^{b} represents a single bond, or a divalent linking group having 1 to 15 carbon atoms and including at least one or more of a phenylene group, a naphthylene group, an ester bond, an ether bond, a lactone ring, an amide group, and a hetero atom. R^{b1} represents an acid-labile group.

Examples of a monomer giving the repeating unit (b) include, but not limited to, those shown below.

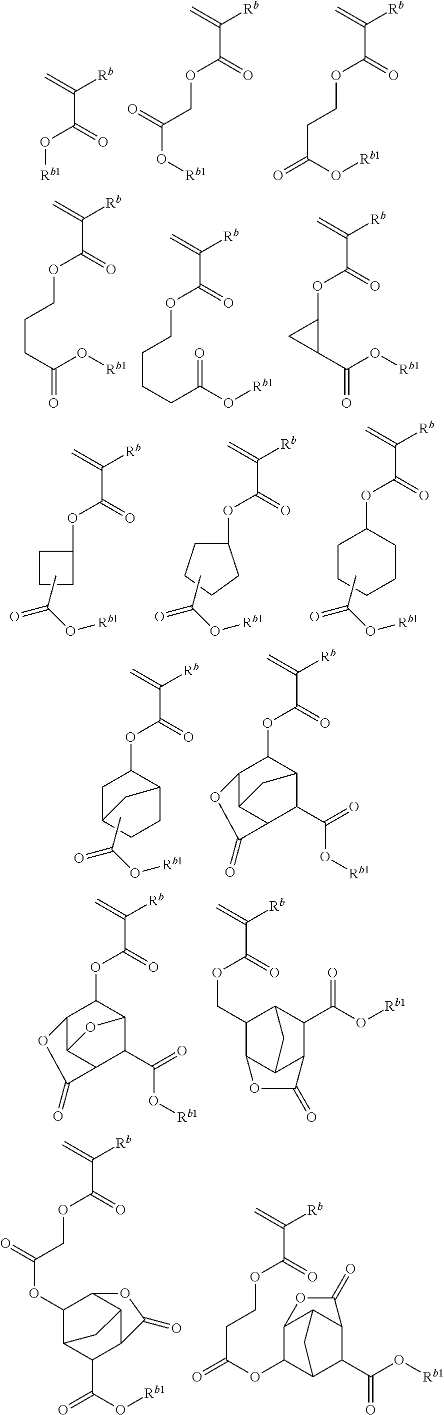

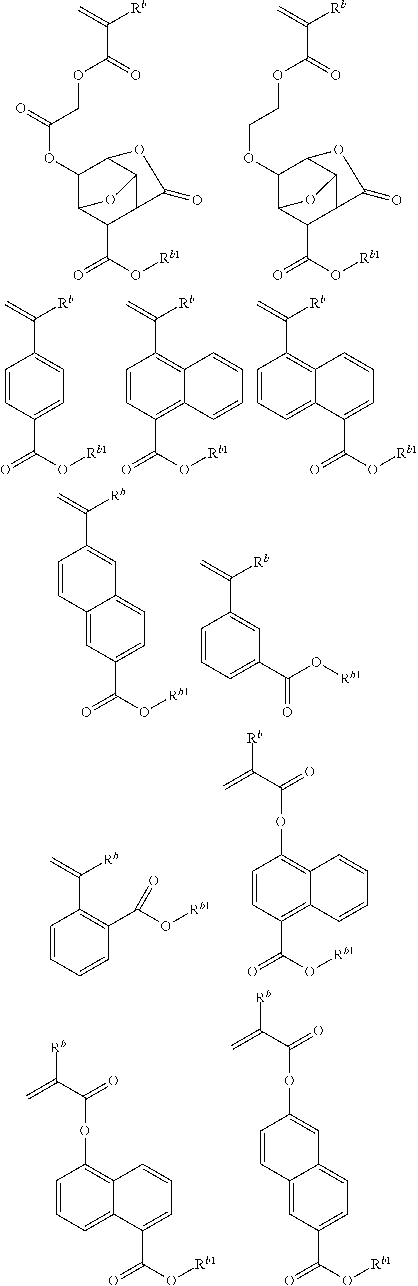

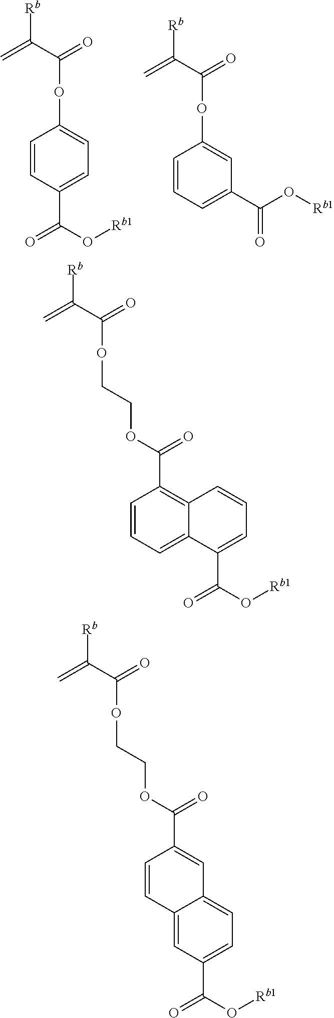

Examples of the acid-labile group represented by R^{b1} include, but not limited to, those groups represented by the following formulas (AL-3)-1 to (AL-3)-19.

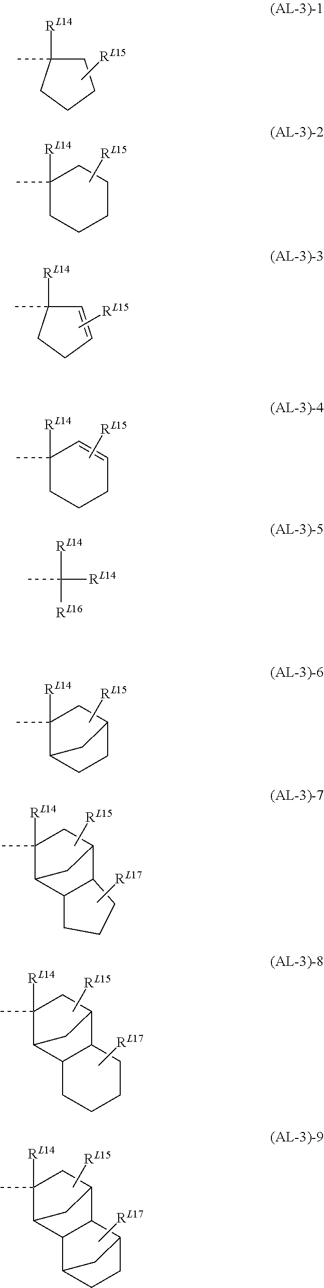

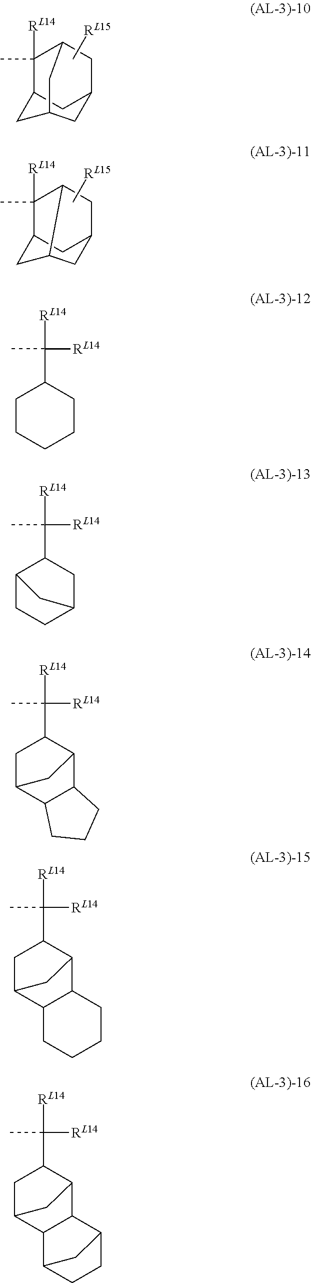

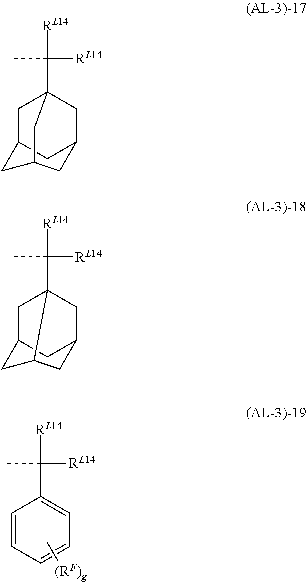

(In the formulas, dashed lines represent connecting bonds.)

In the formulas (AL-3)-1 to (AL-3)-19, R^{L14} each independently represent a saturated hydrocarbyl group having 1 to 8 carbon atoms or an aryl group having 6 to 20 carbon atoms. R^{L15} and R^{L17} each independently represent a hydrogen atom or a saturated hydrocarbyl group having 1 to 20 carbon atoms. R^{L16} represents an aryl group having 6 to 20 carbon atoms. The saturated hydrocarbyl group may be any of linear, branched, or cyclic. The aryl group is preferably a phenyl group, and the like. RF represents a fluorine atom or a trifluoromethyl group. g is an integer of 1 to 5.

The content of the repeating unit (B) in the base polymer (P) is preferably 90 mol % or less, and more preferably 70 mol % or less and 20 mol % or more.

### Crosslinking Agent (II)

The crosslinking agent (II) according to the present invention includes a vinyl ether group which undergoes an addition reaction with a carboxy group or a hydroxyl group contained in a structural unit (A) of the base polymer (P). The crosslinking agent (II) significantly increases the molecular weight by crosslinking the base polymers on a substrate, and thereby suppresses diffusion of acids and dissolution to a developing solution. Further, an acetal structure formed after the crosslinking reaction is decomposed by a strong acid component generated from a component (V) which generates an acid by the exposure described below, so that the molecular weight of only the exposed part is reduced. Accordingly, the contrast between the exposed part and unexposed part is improved.

The crosslinking agent (II) has a structure represented by the following formula (1).

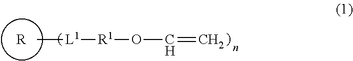

In the formula (1), L¹ represents a linking group selected from a single bond, an ester bond and an ether bond.

In the formula (1), R¹ represents a single bond or a divalent organic group.

In the formula (1), R represents an n-valent organic group which may have a substituent. R preferably includes a cyclic structure, and the cyclic structure is more preferably an aromatic hydrocarbon group.

In the formula (1), n is an integer of 1 to 4. n is preferably 2 or more.

Examples of the crosslinking agent (II) include, but are not limited to, those shown below.

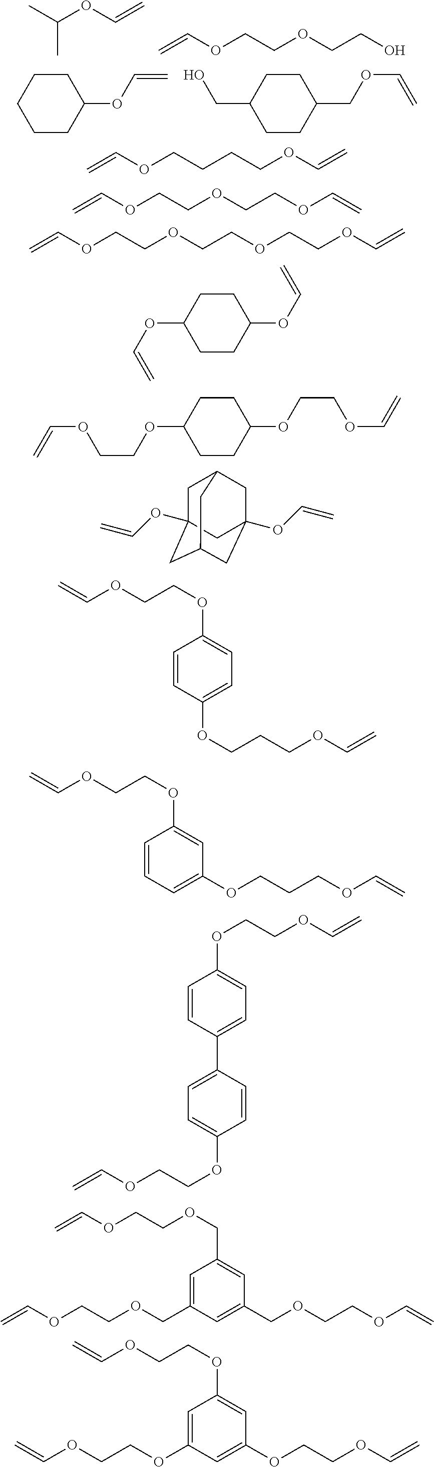

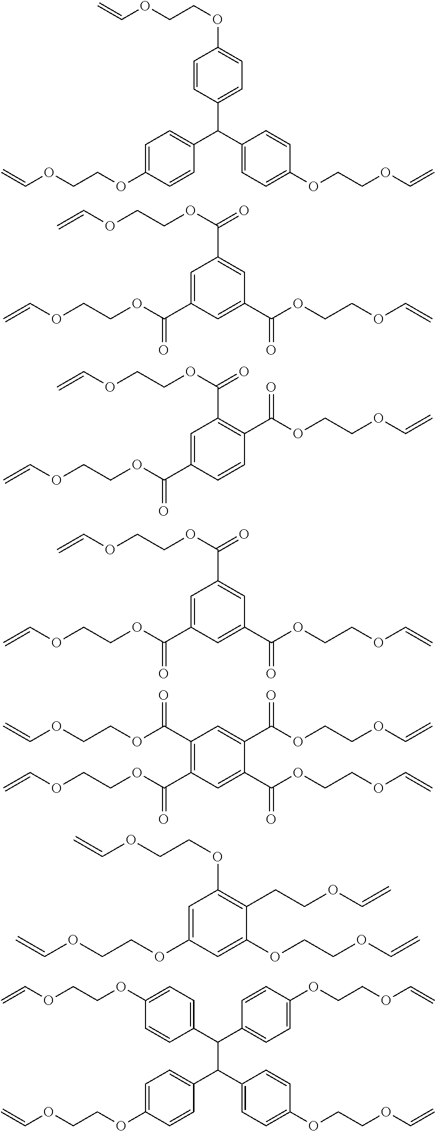

The content of the crosslinking agent (II) is preferably 0.1 to 50 parts by mass, and more preferably 1 to 40 parts by mass, relative to 100 parts by mass of the base polymer. The crosslinking agent (II) may be used singly or in a combination of two or more.

### Quencher (III)

The quencher (III) according to the present invention is a component which traps an acid generated in the exposed part to suppress the diffusion thereof. The quencher (III) is a weak acid salt composed of a carboxylic acid anion and a sulfonium cation, and also has a function as a catalyst for promoting the crosslinking reaction of the crosslinking agent (II).

Such a weak acid generated in the system does not contribute to decomposition of an acetal bond formed by the crosslinking agent (II), but rather functions as an acid catalyst for promoting crosslinking of a remaining unreacted vinyl ether structure.

The quencher (III) has the structure represented by the following formula (2).

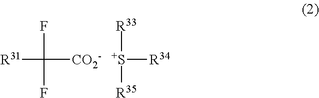

In the formula (2), R³¹ represents a monovalent organic group which may have a substituent. The organic group may include an ether bond, an ester bond, an amide bond, a lactone ring, or a sultone ring. R³¹ preferably contains an aromatic hydrocarbon group, and more preferably contains an iodine atom.

In the formula (2), R³³ to R³⁵ each independently represent a monovalent hydrocarbon group which has 1 to 20 carbon atoms and may contain a hetero atom; and either two of R³³, R³⁴, and R³⁵ may bond to each other to form a ring with the sulfur atom to which they bond.

Examples of an anion structure of the quencher (III) include, but not limited to, those shown below.

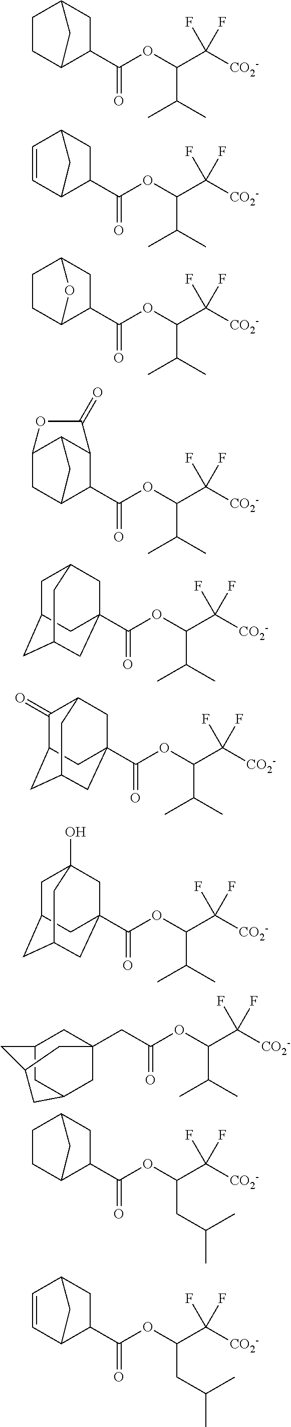

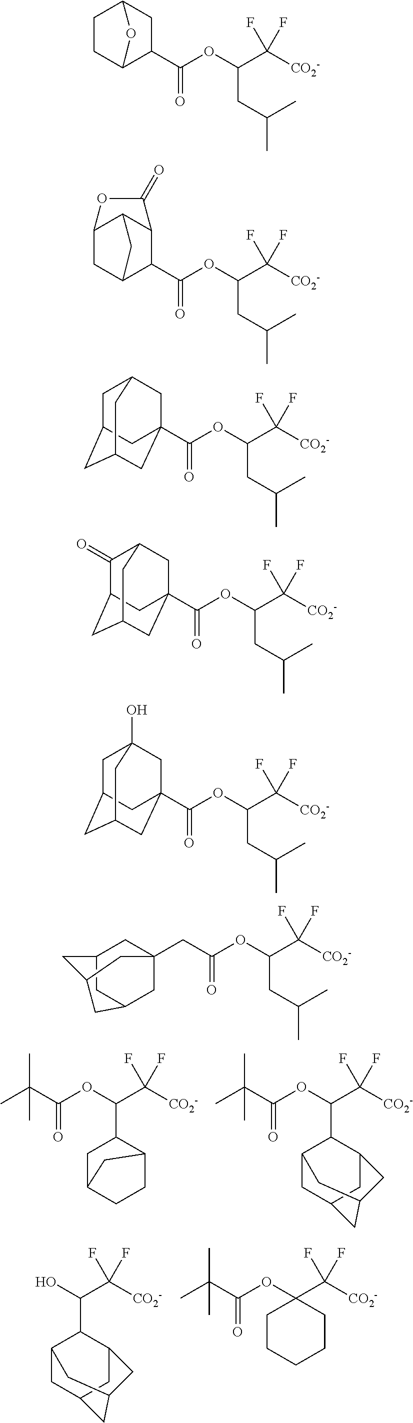

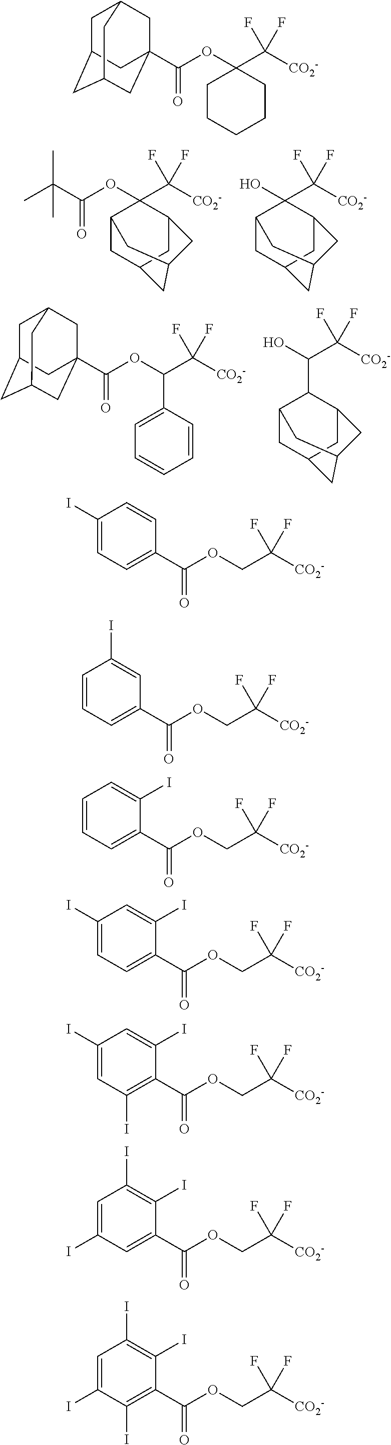

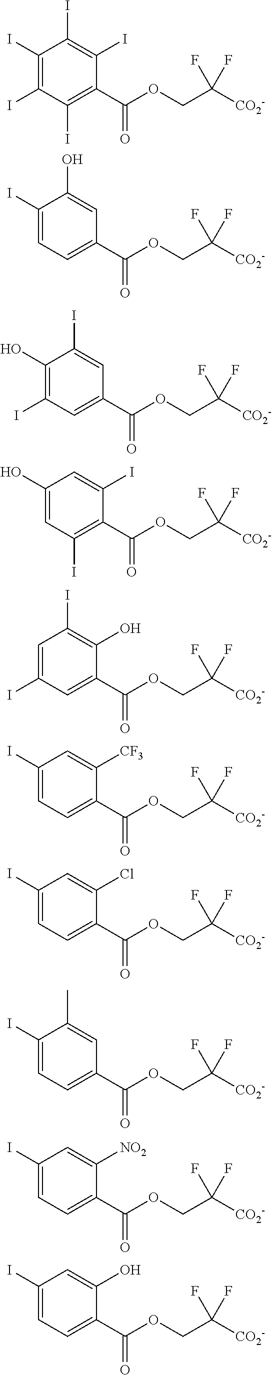

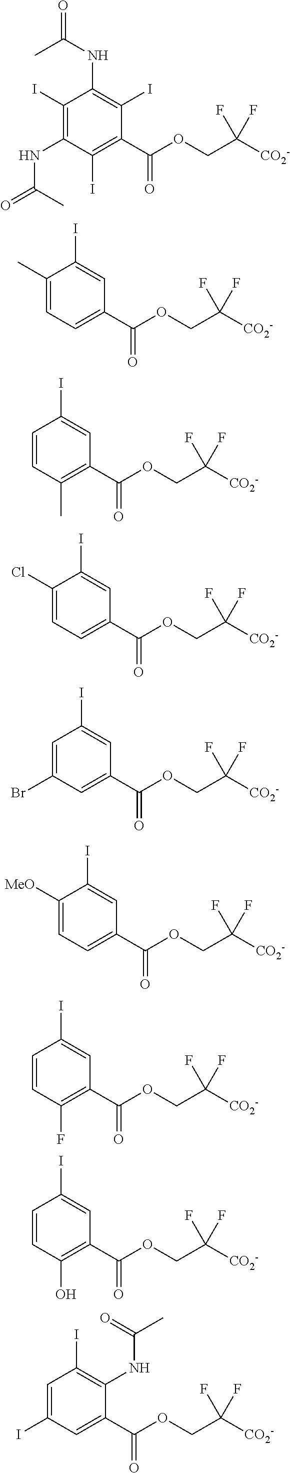

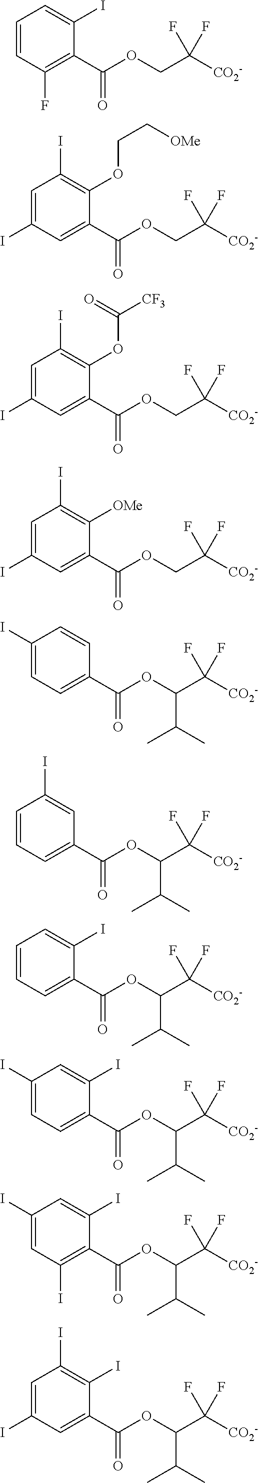

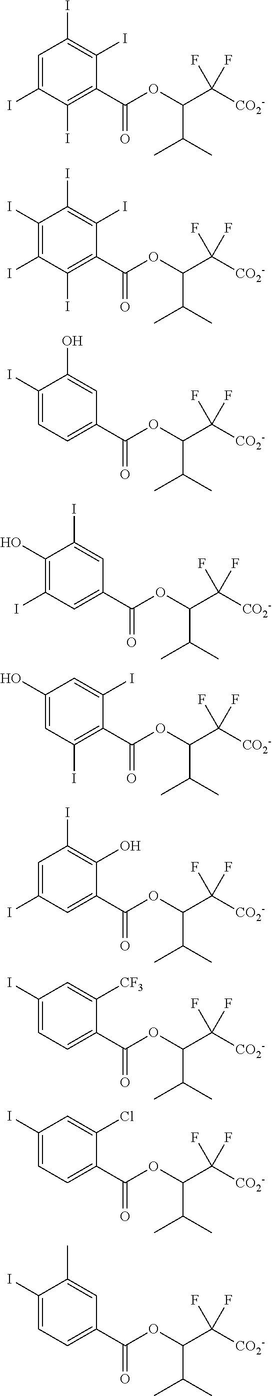

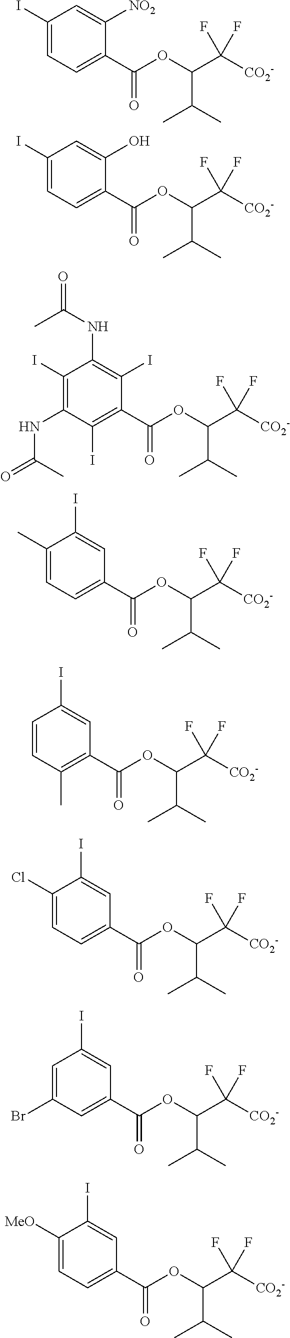

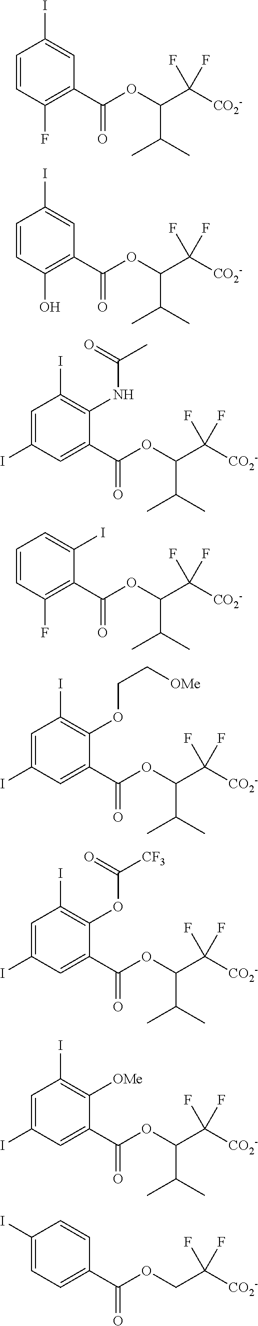

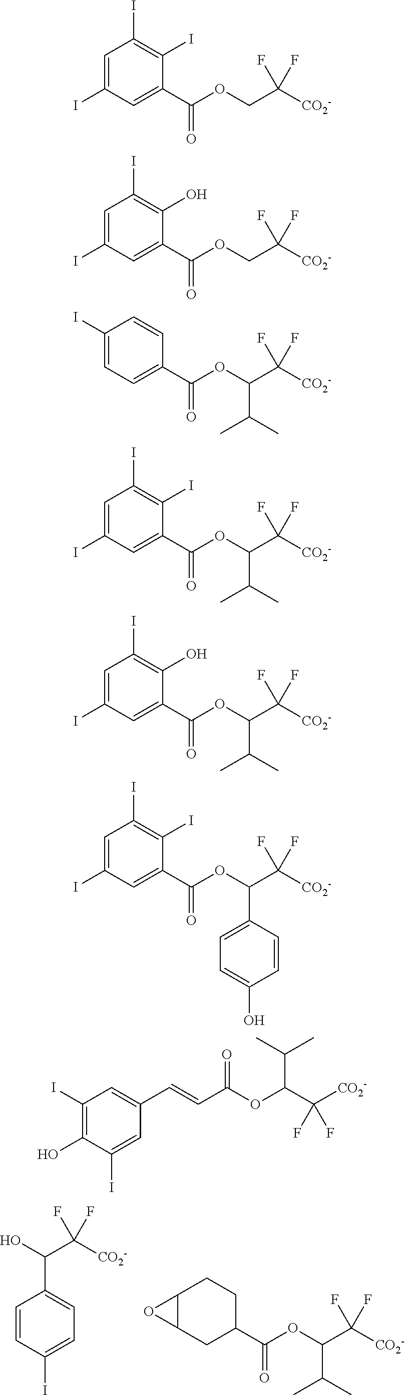

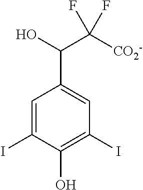

Examples of a cation structure of the quencher (III) are the same as those exemplified as a sulfonium cation in the repeating unit (C) described below.

The content of the quencher (III) in the resist material of the present invention is preferably 0.1 to 50 parts by mass, more preferably 1 to 40 parts by mass relative to 100 parts by mass of the base polymer (P). The quencher (III) may be used singly or in a combination of two or more.

### Organic Solvent (IV)

The resist material of the present invention contains an organic solvent. The organic solvent is not particularly limited as long as each component contained in the resist material of the present invention is soluble. Examples of the organic solvent include ketones such as cyclohexanone, cyclopentanone, methyl-2-n-pentyl ketone, and 2-heptanone; alcohols such as 3-methoxy butanol, 3-methyl-3-methoxy butanol, 1-methoxy-2-propanol, 1-ethoxy-2-propanol, and a diacetone alcohol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropipnate, ethyl 3-ethoxypropionate, tert-butyl acetate, tert-butyl propionate, propylene glycol mono-tert-butyl ether acetate; and lactones such as γ-butyrolactone, which are described in the paragraphs [0144] to [0145] of JP 2008-111103.

In the resist material of the present invention, the content of the organic solvent is preferably 100 to 10,000 parts by mass, and more preferably 200 to 8,000 parts by mass relative to 100 parts by mass of the base polymer. The organic solvent may be used singly, or two or more of them may be used as a mixture.

### (V) Component Decomposed by Irradiation of Active Ray or Radiant Ray to Generate Acid

The resist material of the present invention further contains a photoacid generator. The acid generated from a photoacid generator by pattern exposure is a strong acid which has stronger acidity than the quencher (III), and decomposes the acid-labile group contained in the repeating unit (B) and the acetal bond formed by the crosslinking agent (II). Accordingly, the polarity change and molecular weight reduction occur in the exposed part of the resist film, so that dissolution contrast with unexposed part is improved.

Examples of the photoacid generator include a compound which generates an acid in response to an active ray or a radiant ray. The photoacid generator may be any compound which generates an acid by irradiation of a high energy ray, and is preferably one generating a sulfonic acid, an imide acid, or a methide acid. Examples of a preferable photoacid generator include a sulfonium salt, an iodonium salt, sulfonyl diazomethane, N-sulfonyloxyimide, and an oxime-O-sulfonate photoacid generator. Specific examples of the photoacid generator include those described in the paragraphs [0122] to [0142] of JP 2008-111103.

The content of the photoacid generator (V) in the resist material of the present invention is preferably 0.1 to 50 parts by mass, and more preferably 1 to 40 parts by mass relative to 100 parts by mass of the base polymer (P). The photoacid generator (V) may be used singly or in a combination of two or more.

As the photoacid generator, a sulfonium salt represented by the following formula (3) may be suitably used.

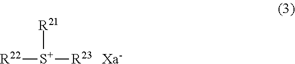

In the formula (3), R²¹ to R²³ each independently represent a halogen atom or a hydrocarbyl group which has 1 to 20 carbon atoms and may contain a hetero atom. The hydrocarbyl group may be any of linear, branched, or cyclic. The specific examples thereof are the same as those exemplified in the description of R^{c2} to R^{c4} in the formula (c) described below. A part or all of hydrogen atoms in these groups may be substituted with a group containing a hetero atom such as an oxygen atom, a sulfur atom, a nitrogen atom, and a halogen atom. A part of —CH₂— of these groups may be substituted with a group containing a hetero group such as an oxygen atom, a sulfur atom, and a nitrogen atom. As a result, a hydroxy group, a fluorine atom, a chlorine atom, a bromine atom, an iodine atom, a cyano group, a nitro group, a carbonyl group, an ether bond, an ester bond, a sulfonic acid ester bond, a carbonate bond, a lactone ring, a sultone ring, a carboxylic acid anhydride, a haloalkyl group, and the like may be contained. Further, R²¹ and R²² may bond to each other to form a ring with the sulfur atom to which they bond. On this occasion, examples of the ring are the same as those exemplified in the description of the formula (c) which either two of R^{c2}, R^{c3}, and R^{c4} may bond to each other to form with the sulfur atom to which they bond.

Examples of the cation of the sulfonium salt represented by the formula (3) are the same as those exemplified as a sulfonium cation of the monomer giving the repeating unit (C) described below.

In the formula (3), Xa⁻ is an anion selected from the following formulas (3A) to (3D).

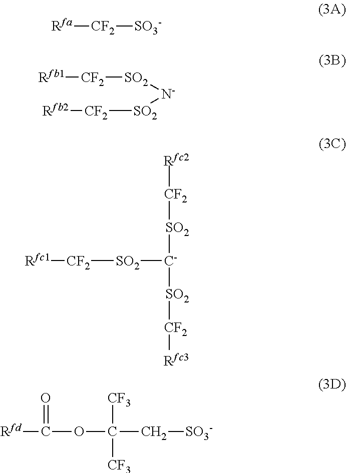

In the formula (3A), R^{fa} represents a fluorine atom or a hydrocarbyl group which has 1 to 40 carbon atoms and may contain a hetero atom. The hydrocarbyl group may be saturated or unsaturated, and may be any of linear, branched, or cyclic. Specific examples thereof are the same as those exemplified as the hydrocarbyl group represented by R¹¹¹ in the formula (3A′) described below.

The anion represented by the formula (3A) is preferably one represented by the following formula (3A′).

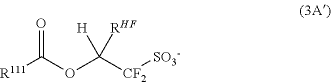

In the formula (3A′), R^{HF} represents a hydrogen atom or a trifluoromethyl group, and is preferably a trifluoromethyl group. R¹¹¹ represents a hydrocarbyl group which has 1 to 38 carbon atoms and may contain a hetero atom. The hetero atom is preferably an oxygen atom, a nitrogen atom, a sulfur atom, a halogen atom, and the like, and is more preferably an oxygen atom. The hydrocarbyl group particularly preferably has 6 to 30 carbon atoms in view of obtaining high resolution in forming a fine pattern.

The hydrocarbyl group represented by R¹¹¹ may be saturated or unsaturated, and may be any of linear, branched, or cyclic. Specific examples thereof include alkyl groups having 1 to 38 carbon atoms such as a methyl group, ethyl group, n-propyl group, isopropyl group, butyl group, isobutyl group, sec-butyl group, tert-butyl group, pentyl group, neopentyl group, hexyl group, heptyl group, 2-ethylhexyl group, nonyl group, undecyl group, tridecyl group, pentadecyl group, heptadecyl group, and icosanyl group; cyclic saturated hydrocarbyl groups having 3 to 38 carbon atoms such as a cyclopentyl group, cyclohexyl group, 1-adamantyl group, 2-adamantyl group, 1-adamantyl methyl group, norbornyl group, norbornyl methyl group, tricyclodecanyl group, tetracyclododecanyl group, tetracyclododecanyl methyl group, and dicyclohexylmethyl group; unsaturated aliphatic hydrocarbyl groups having 2 to 38 carbon atoms such as an allyl group and a 3-cyclohexenyl group; aryl groups having 6 to 38 carbon atoms such as a phenyl group, 1-naphthyl group, and 2-naphthyl group; aralkyl groups having 7 to 38 carbon atoms such as a benzyl group and diphenylmethyl group; a group obtained by combining these groups, and the like.

A part or all of hydrogen atoms in these groups may be substituted with a group containing a hetero atom such as an oxygen atom, sulfur atom, nitrogen atom, and halogen atom. A part of —CH₂— in these groups may be substituted with a group containing a hetero atom such as an oxygen atom, a sulfur atom, and a nitrogen atom. As a result, a hydroxy group, fluorine atom, chlorine atom, bromine atom, iodine atom, cyano group, nitro group, carbonyl group, ether bond, ester bond, sulfonic acid ester bond, carbonate bond, lactone ring, sultone ring, carboxylic acid anhydride, haloalkyl group, and the like may be contained. Examples of the hydrocarbyl group containing a hetero atom include a tetrahydrofuryl group, methoxymethyl group, ethoxymethyl group, methylthiomethyl group, acetamidemethyl group, trifluoroethyl group, (2-methoxyethoxy)methyl group, acetoxymethyl group, 2-carboxy-1-cyclohexyl group, 2-oxopropyl group, 4-oxo-1-adamanthyl group, and 3-oxocyclohexyl group.

Synthesis of a sulfonium salt containing the anion represented by the formula (3A′) is described in detail in JP 2007-145797, JP 2008-106045, JP 2009-7327, JP 2009-258695, and the like. Further, the sulfonium salts described in JP 2010-215608, JP 2012-41320, JP 2012-106986, and JP 2012-153644 can also be suitably used.

Examples of the anion represented by the formula (3A) are the same as those anions exemplified in the formula (1A) in JP 2018-197853.

In the formula (3B), R^{fb1} and R^{fb2} each independently represent a fluorine atom or a hydrocarbyl group which has 1 to 40 carbon atoms and may contain a hetero atom. The hydrocarbyl group may be saturated or unsaturated, and may be any of linear, branched, or cyclic. Specific examples thereof are the same as those exemplified as the hydrocarbyl group represented by R¹¹¹ in the formula (3A′). R^{fb1} and R^{fb2} are preferably a fluorine atom or a linear fluorinated alkyl group having 1 to 4 carbon atoms. R^{fb1} and R^{fb2} may bond to each other to from a ring with the group (—CF₂—SO₂—N⁻—SO₂—CF₂—) to which they bond. On this occasion, a group obtained by bonding R^{fb1} and R^{fb2} each other is preferably a fluorinated ethylene group or fluorinated propylene group.

In the formula (3C), R^{fc1}, R^{fc2} and R^{fc3} each independently represent a fluorine atom or a hydrocarbyl group which has 1 to 40 carbon atoms and may contain a hetero atom. The hydrocarbyl group may be saturated or unsaturated, and may be any of linear, branched, or cyclic. Specific examples thereof are the same as those exemplified as the hydrocarbyl group represented by R¹¹¹ in the formula (3A′). R^{fc1}, R^{fc2} and R^{fc3} are preferably a fluorine atom or a linear fluorinated alkyl group having 1 to 4 carbon atoms. R^{fc1} and R^{fc2} may bond to each other to from a ring with the group (—CF₂—SO₂—C⁻—SO₂—CF₂—) to which they bond. On this occasion, a group obtained by bonding R^{fc1} and R^{fc2} each other is preferably a fluorinated ethylene group or fluorinated propylene group.

In the formula (3D), R^{fd} represents a hydrocarbyl group which has 1 to 40 carbon atoms and may contain a hetero atom. The hydrocarbyl group may be saturated or unsaturated, and may be any of linear, branched, or cyclic. Specific examples thereof are the same as those exemplified as the hydrocarbyl group represented by R¹¹¹ in the formula (3A′).

Synthesis of a sulfonium salt containing the anion represented by the formula (3D) is described in detail in JP 2010-215608 and JP 2014-133723.

Examples of the anion represented by the formula (3D) are the same as those exemplified as anions represented by the formula (1D) in JP 2018-197853.

A photoacid generator containing the anion represented by the formula (3D) does not have a fluorine atom at the α-position of the sulfo group, but has two trifluoromethyl groups at the β-position, and thereby has sufficient acidity to cleave an acid-labile group in the base polymer. Accordingly, it can be used as a photoacid generator.

### Surfactant

The positive resist material of the present invention may include a surfactant in addition to the above-mentioned components.

Examples of the surfactant include those described in the paragraphs [0165] to [0166] in JP 2008-111103. By adding a surfactant, applicability of the resist material can be further improved or controlled. When the positive resist material of the present invention contains the surfactant, the content thereof is preferably 0.0001 to 10 parts by mass relative to 100 parts by mass of the base polymer. The surfactant may be used singly or in a combination of two or more kinds.

### Second Aspect

The second aspect of the present invention is a resist material containing the above (Ib), (II), (III), and (IV). While in the first aspect of the present invention, an additive-type photoacid generator is used as the component (V) other than the base polymer (Ia), in the second aspect of the present invention, the base polymer (Ib) itself functions as a photoacid generator. Hereinafter, each component will be described in detail.

### Base Polymer (Ib)

The base polymer (P) according to the present invention is a polymer containing the repeating unit (A) including a hydroxyl group or carboxy group, and the repeating unit (C) having a structural site which is decomposed by irradiation of an active ray or a radiant ray to generate an acid.

The repeating unit (A) may be the same as those described in the base polymer (Ia).

The base polymer contains the repeating unit (C) having a structural site which is decomposed by irradiation of an active ray or a radiant ray to generate an acid. Since the repeating unit (C) has high polarity, a polymer containing the repeating unit (C) and having a low molecular weight has high solubility to an alkaline developing solution. On the other hand, by increasing the molecular weight of such an easily soluble component by crosslinking, the solubility to a developing solution is significantly decreased. By this effect, the dissolution contrast between crosslinked part and uncrosslinked part can be greatly changed.

As the repeating unit (C), the repeating unit (C) represented by the following formula (c) may be used.

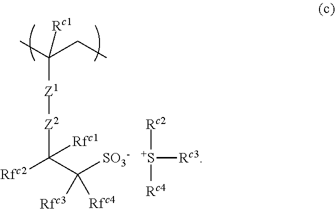

In the formula (c), R^{c1} represents a hydrogen atom or a methyl group.

In the formula (c), Z¹ represents a single bond or an ester bond. Z² represents a single bond or a divalent organic group having 1 to 25 carbon atoms, and may include an ester bond, an ether bond, a lactone ring, an amide bond, a sultone ring, or an iodine atom. Z² may be any of linear, branched, or cyclic. Specific examples thereof include alkane diyl groups having 1 to 20 carbon atoms such as a methane-diyl group, an ethane-1,1-diyl group, an ethane-1,2-diyl group, a propane-1,2-diyl group, a propane-1,3-diyl group, a propane-2,2-diyl group, a butane-1,2-diyl group, a butane-1,3-diyl group, a butane-1,4-diyl group, a butane-2,2-diyl group, a butane-2,3-diyl group, a 2-methylpropane-1,3-diyl group, a pentane-1,5-diyl group, a hexane-1,6-diyl group, a heptane-1,7-diyl group, an octane-1,8-diyl group, a nonane-1,9-diyl group, and a decane-1,10-diyl group; cyclic saturated hydrocarbylene groups having 3 to 20 carbon atoms such as a cyclopentanediyl group, a cyclohexanediyl group, a norbornanediyl group, and an adamantanediyl group; a group obtained by combining these groups, and the like.

In the formula (c), Rf^{c1} to Rf^{c4} each independently represent a hydrogen atom, a fluorine atom, or a trifluoromethyl group, and at least one of Rf^{c1} to Rf^{c4} is a fluorine atom.

In the formula (c), R^{c2} to R^{c4} each independently represent a monovalent hydrocarbon group which has 1 to 20 carbon atoms and may contain a hetero atom.

Further, either two of R^{c2}, R^{c3}, and R^{c4} may bond to each other to form a ring with the sulfur atom to which they bond. On this occasion, the ring is preferably those shown below.

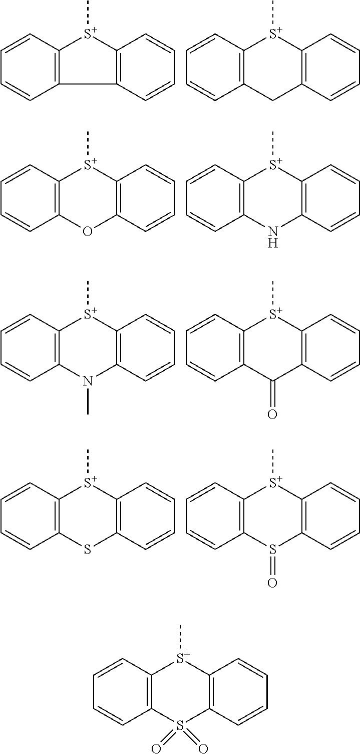

(In the formulas, dashed lines represent connecting bonds with R^{c4}.)

Examples of the anion structure of the monomer giving the repeating unit (C) include, but not limited to, those shown below.

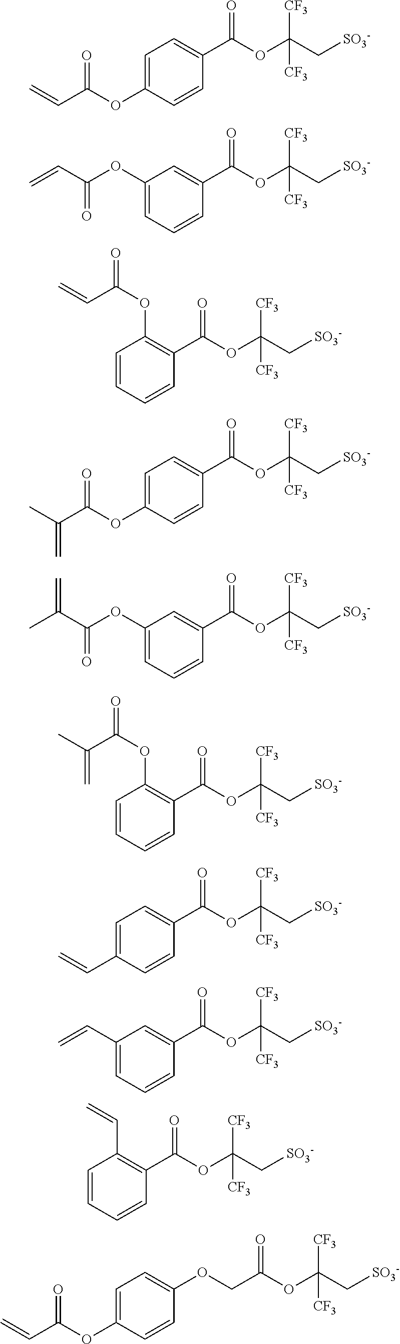

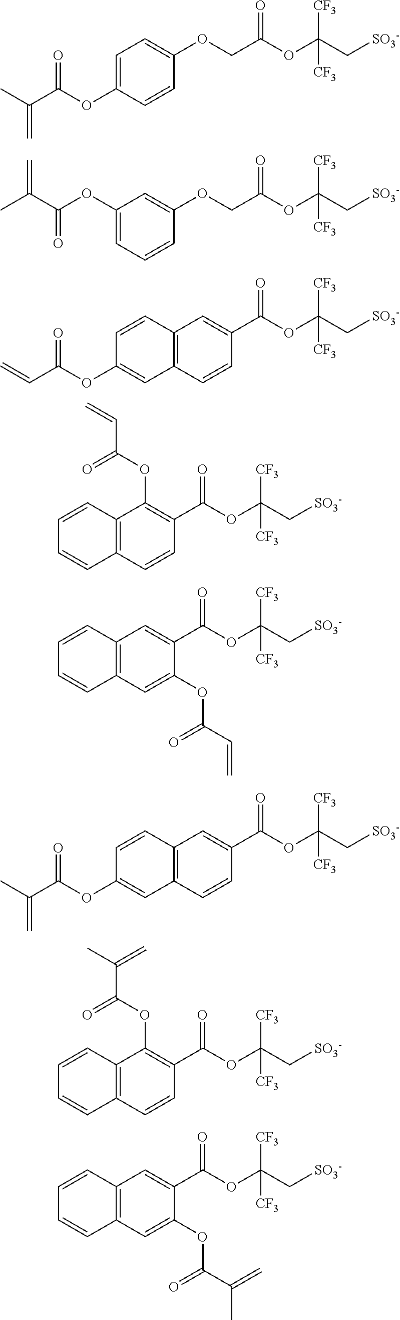

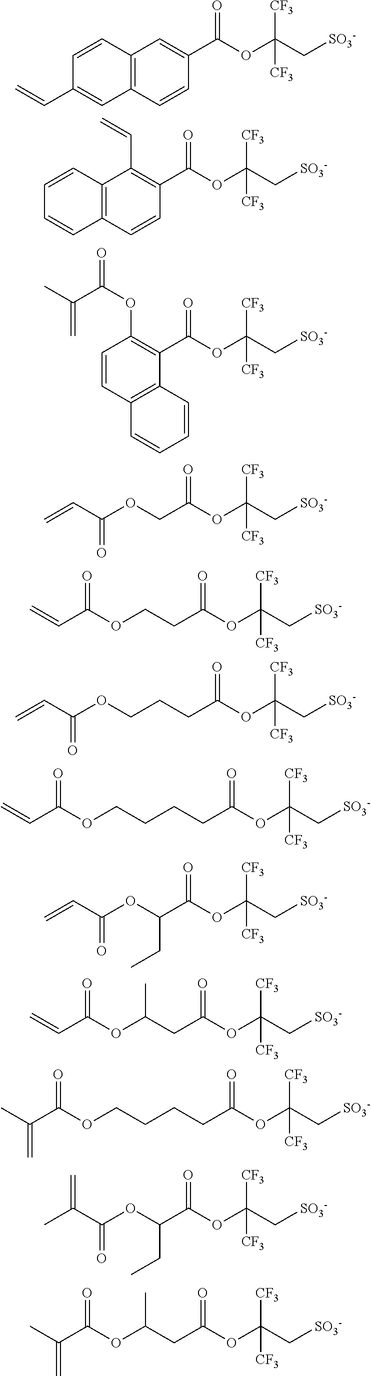

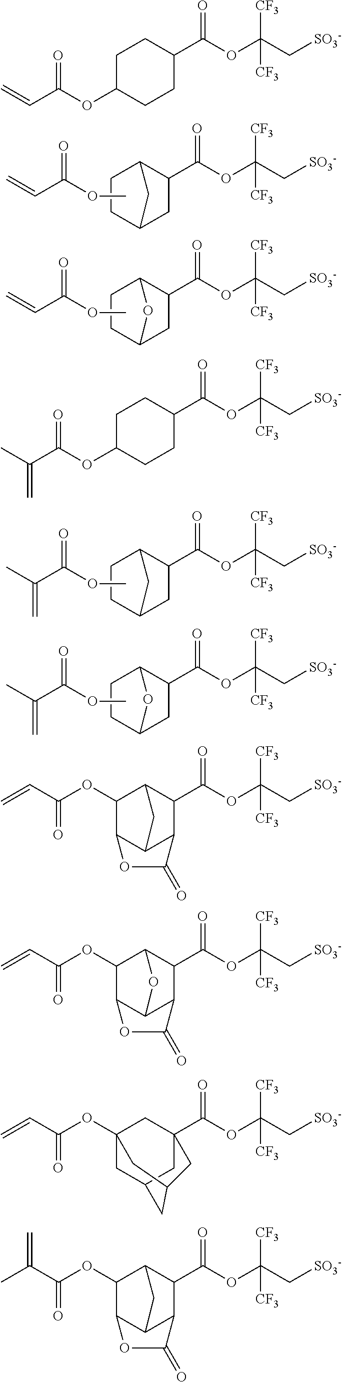

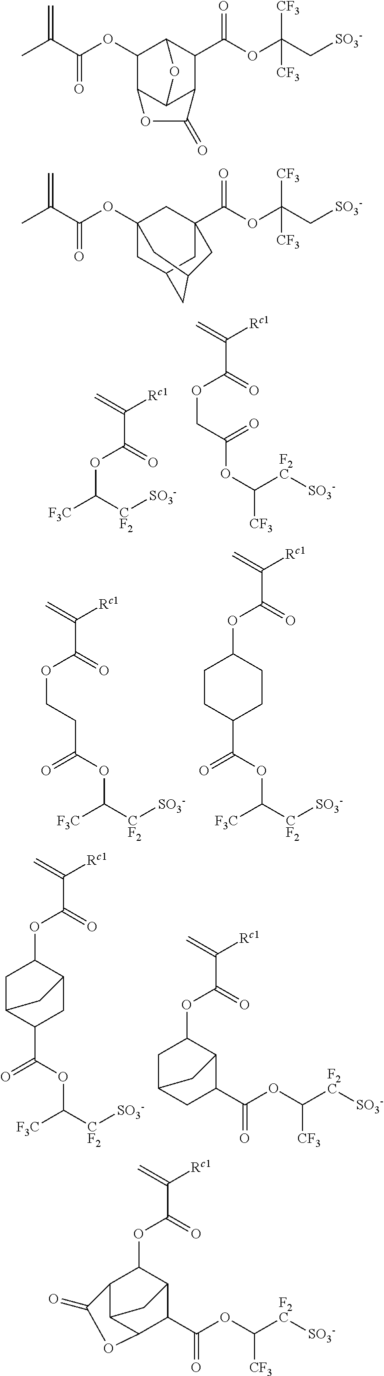

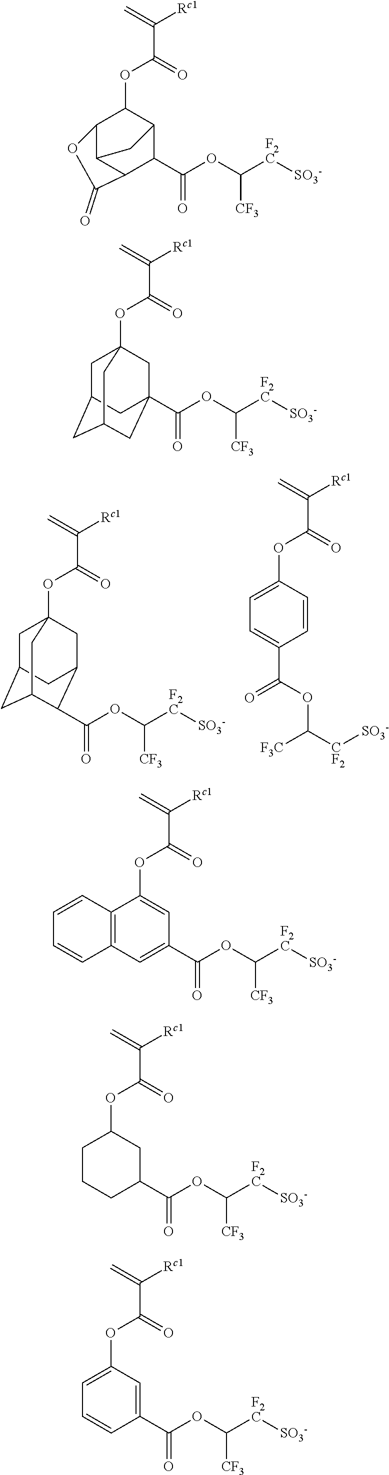

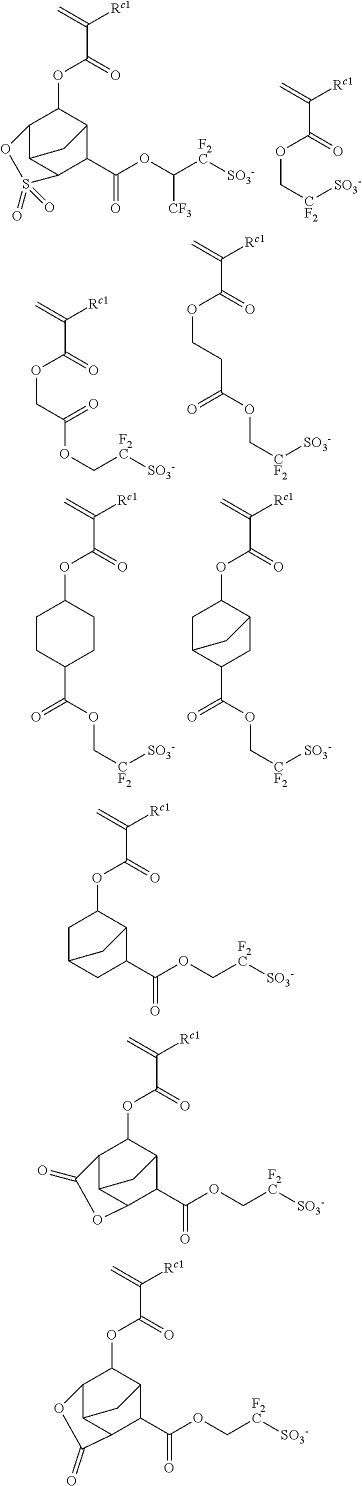

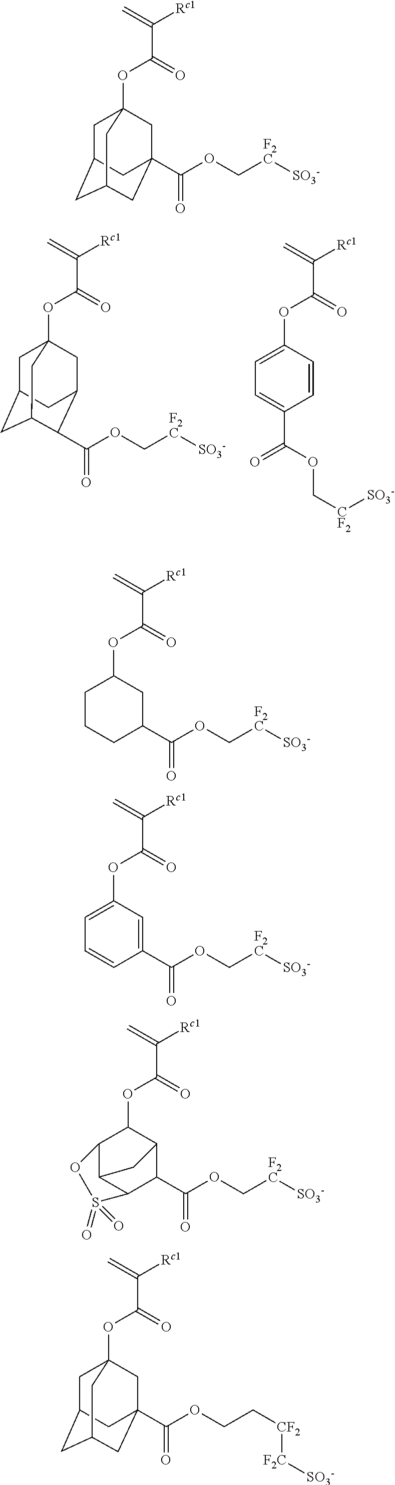

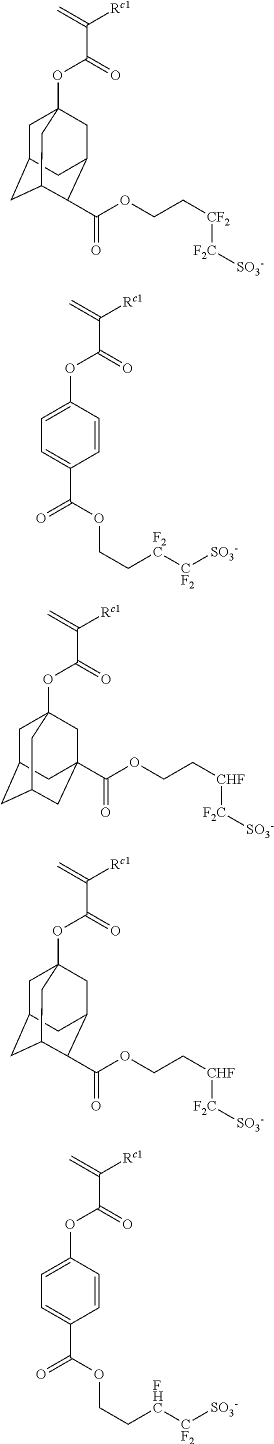

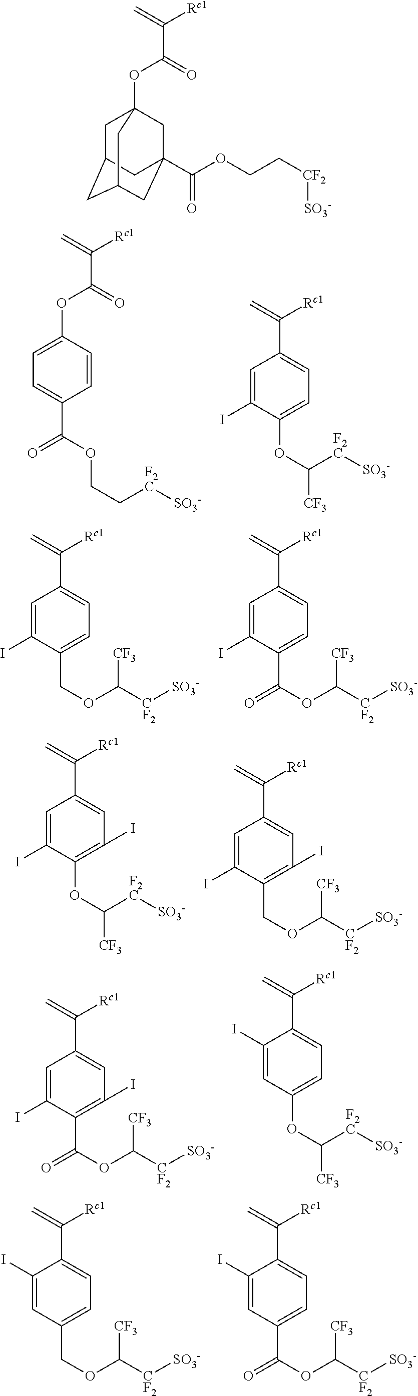

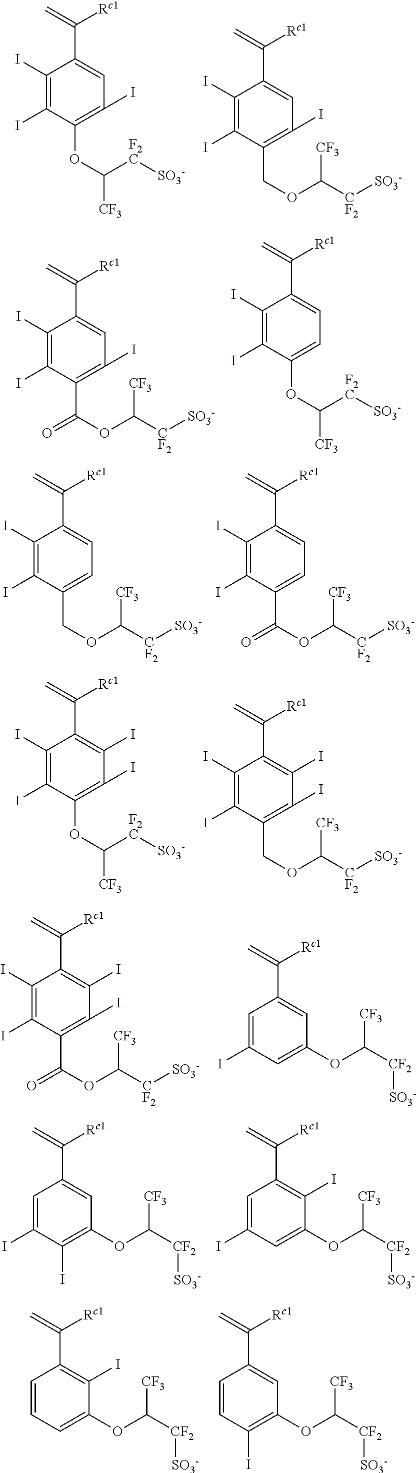

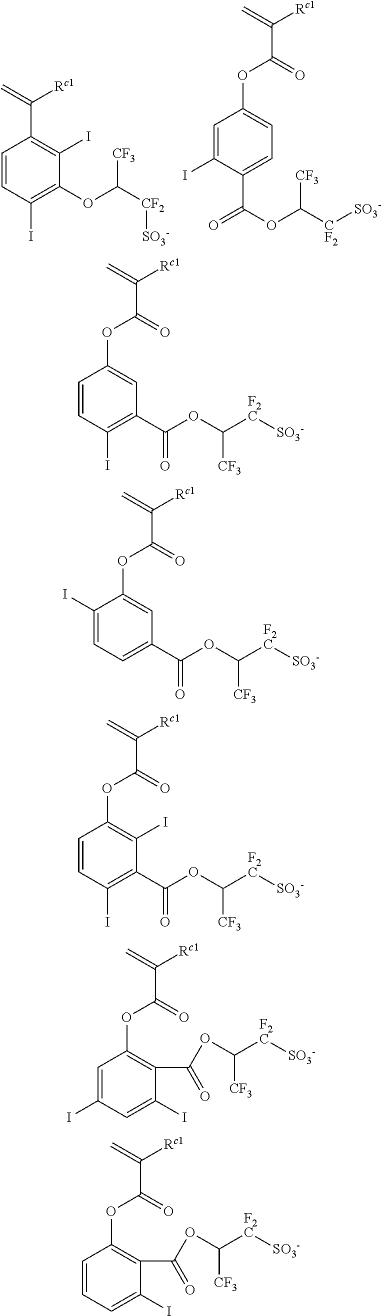

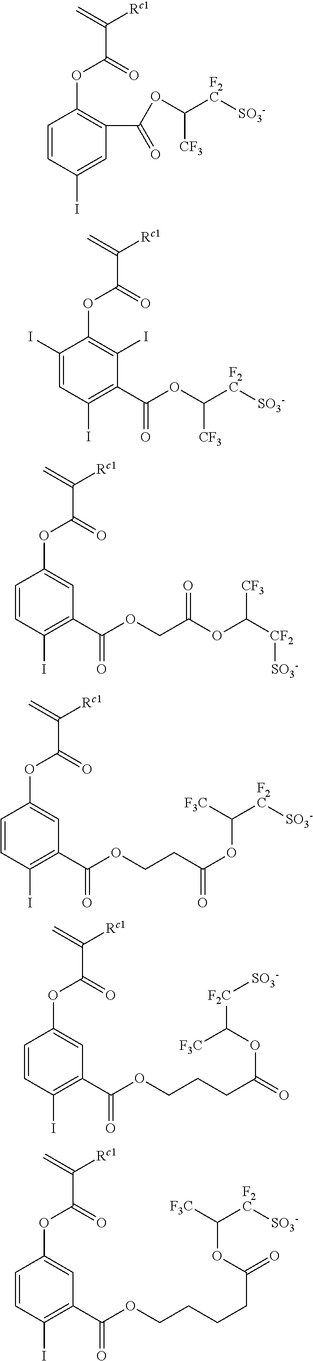

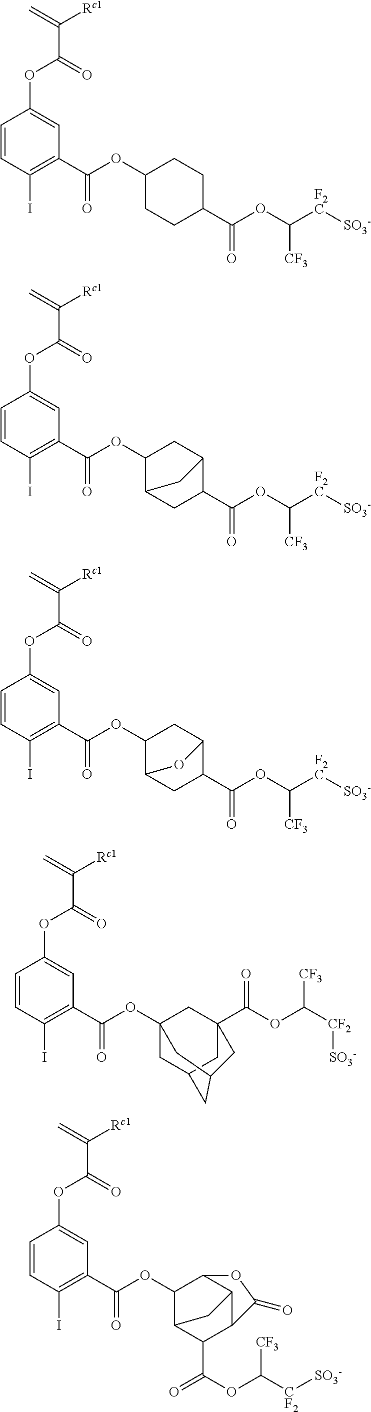

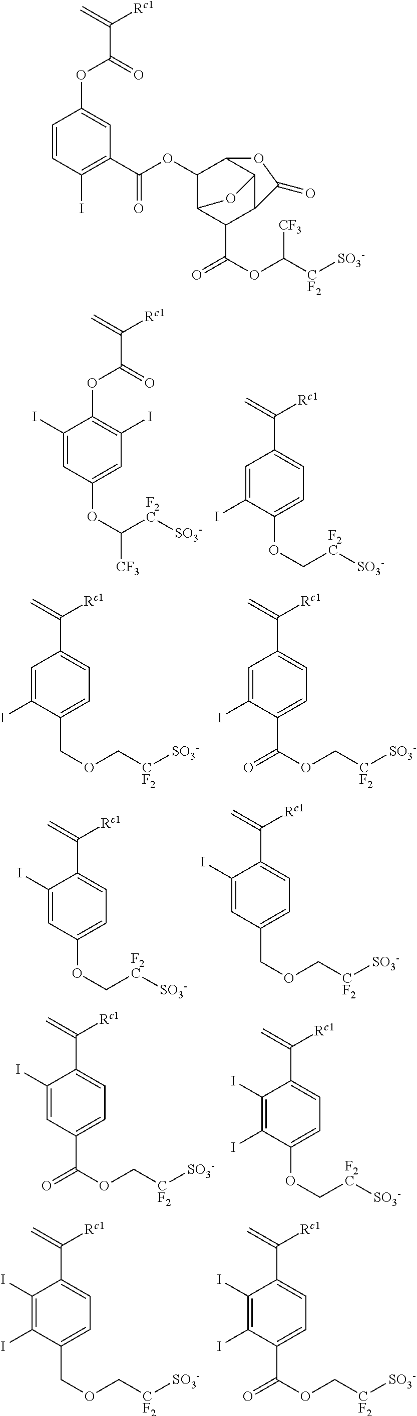

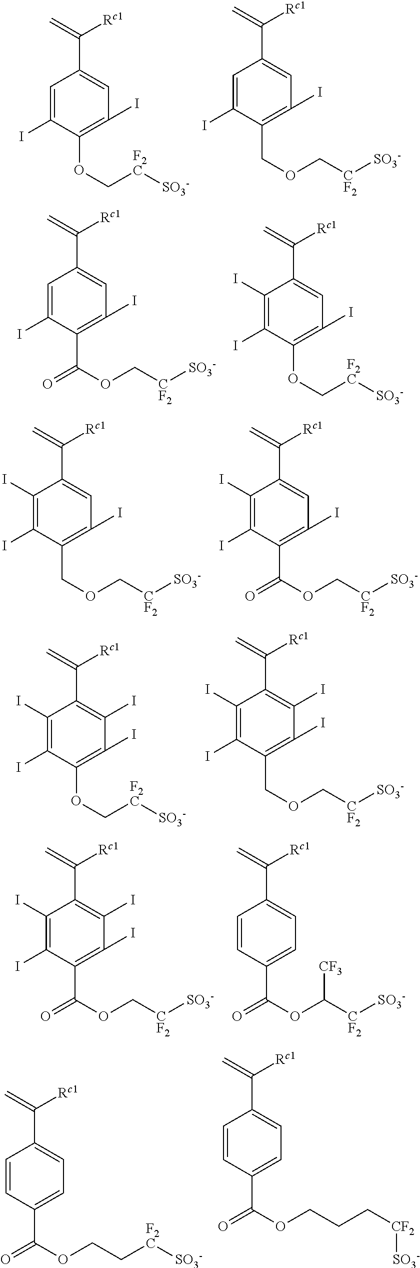

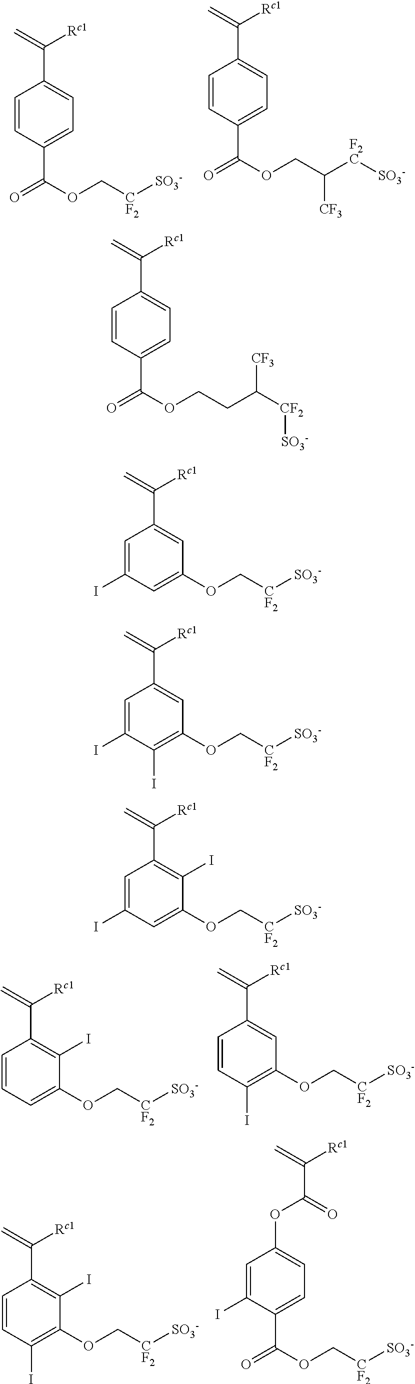

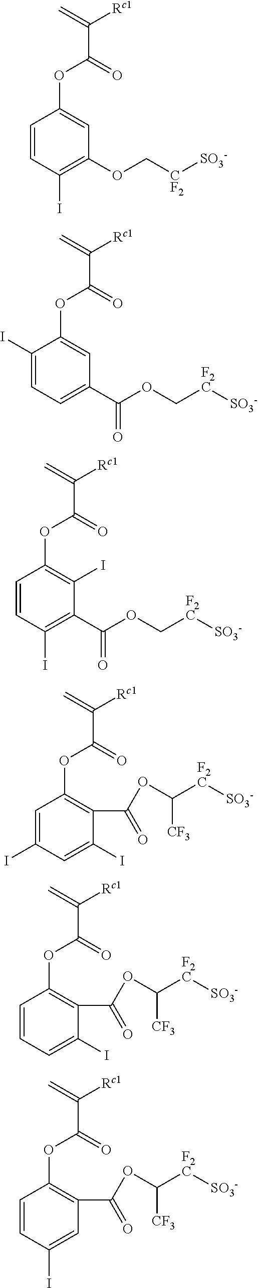

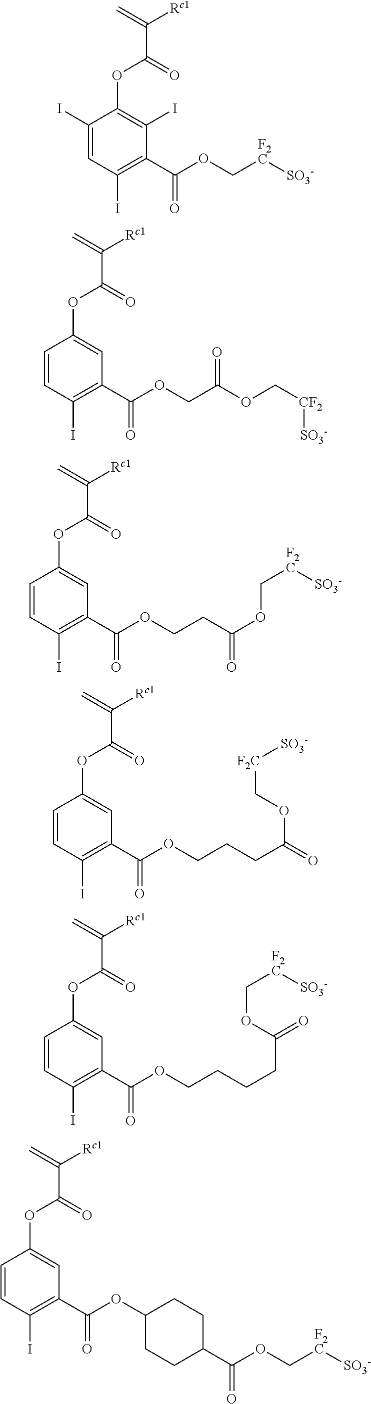

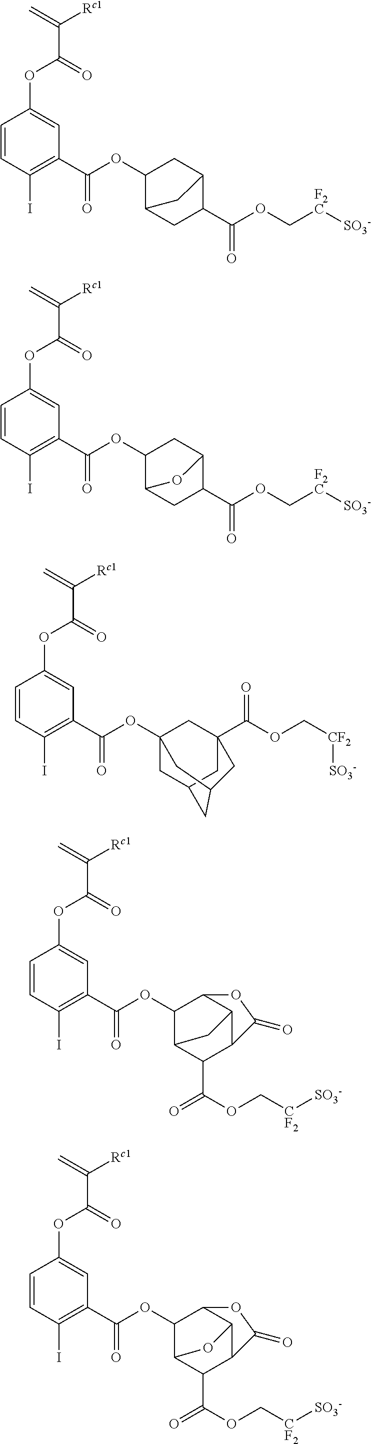

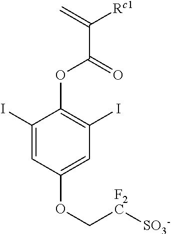

Examples of the sulfonium cation of the monomer giving the repeating unit (C) include, but not limited to, those shown below.

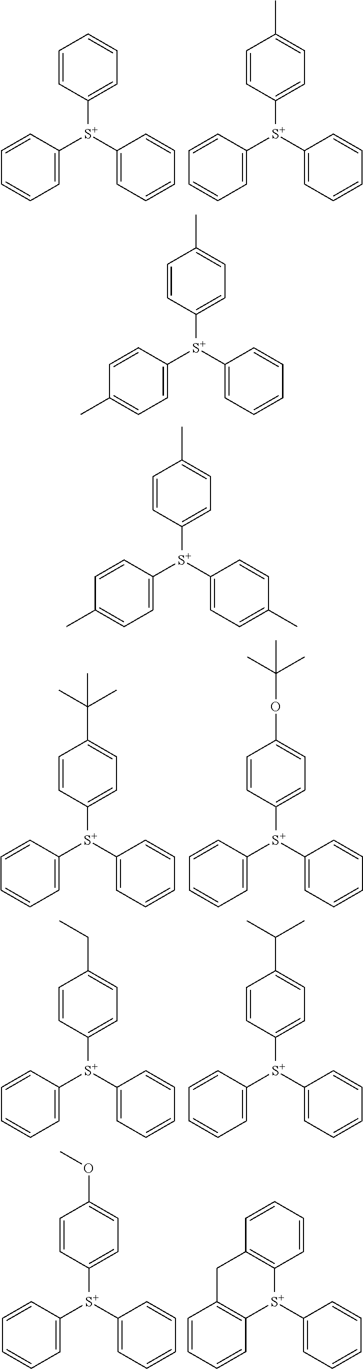

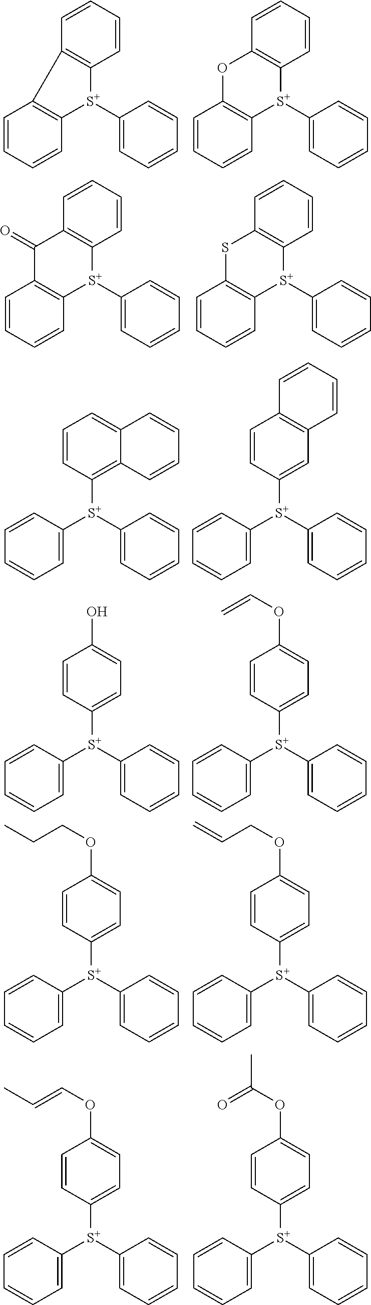

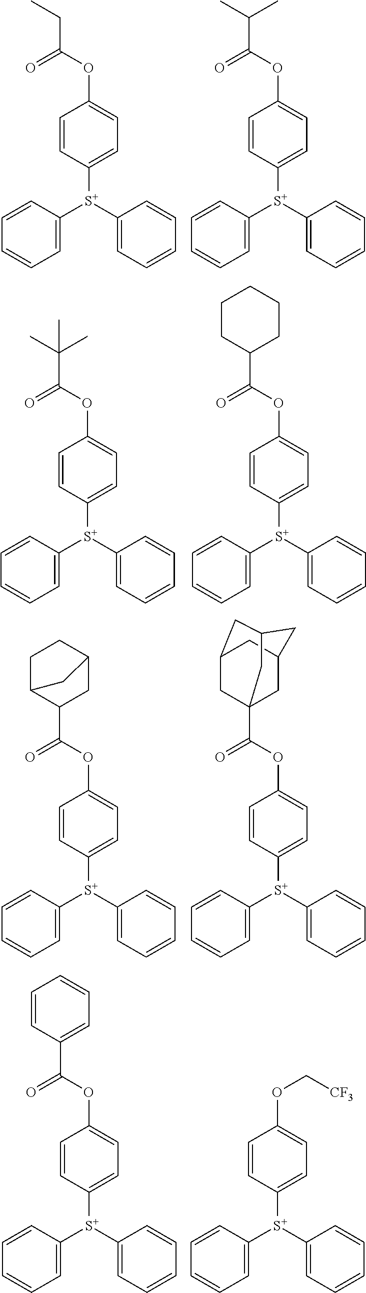

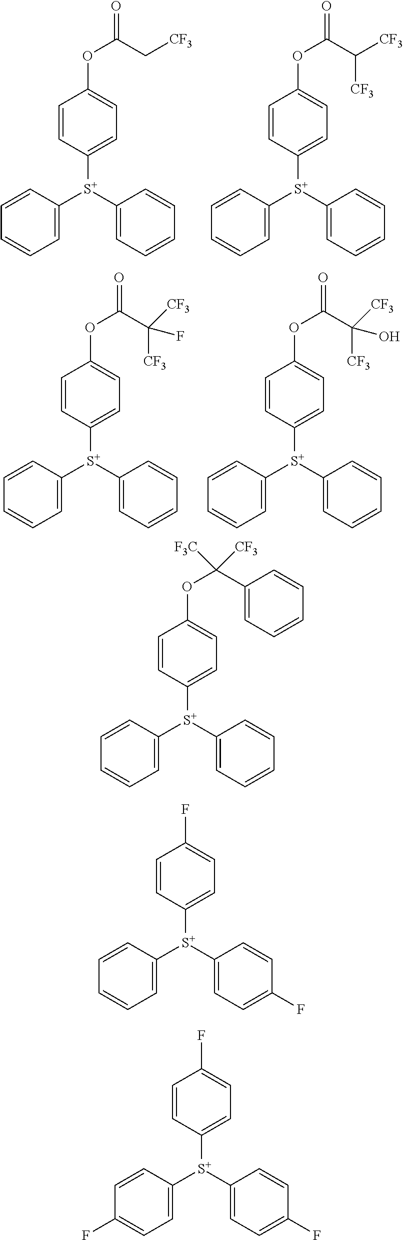

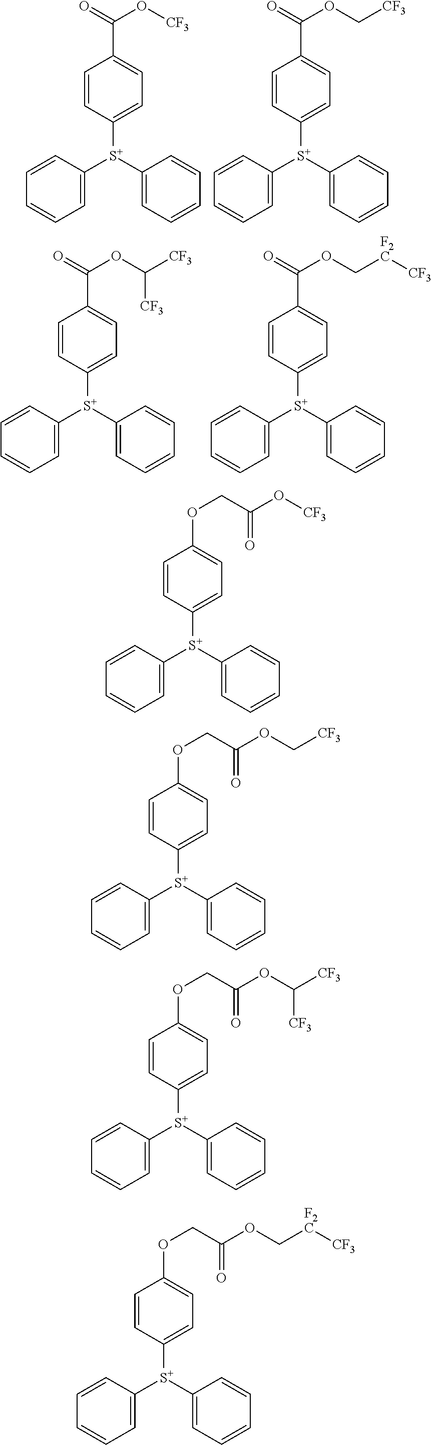

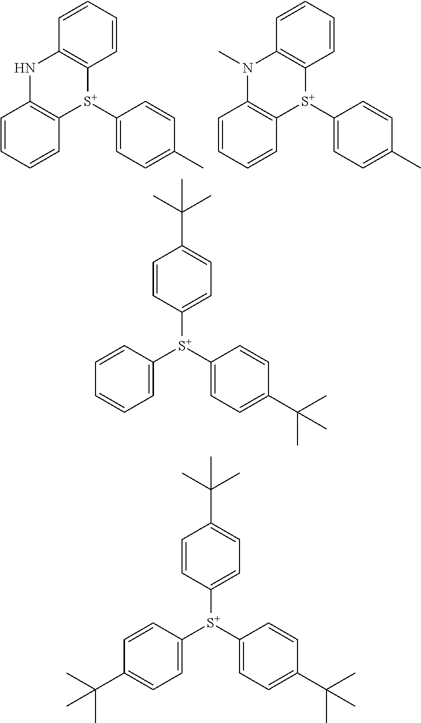

The base polymer (P) preferably contains the repeating unit (B) obtained by substituting the hydrogen atom in the carboxy group in the repeating unit (A) with an acid-labile group in addition to the repeating units (A) and (C). The repeating unit (B) may be the same as those described in the base polymer (Ia) above.

The content of the repeating unit (C) in the base polymer (P) is preferably 50 mol % or less, and more preferably 30 mol % or less and 5 mol % or more.

### Crosslinking Agent (II)

The crosslinking agent (II) may be the same as those described in the above first aspect.

### Quencher (III)

The quencher (III) may be the same as those described in the above first aspect.

### Organic Solvent (IV)

The organic solvent (IV) may be the same as those described in the above first aspect.

### (V) Component to be Decomposed by Irradiation of Active Ray or Radiant Ray to Generate Acid

In the resist material of the second aspect of the present invention, the additive-type photoacid generator may be blended as the component (V). The component (V) may be the same as those described in the above first aspect.

### Surfactant

A surfactant may be blended in the resist material of the second aspect of the present invention. The surfactant may be the same as those described in the above first aspect.

### Pattern Forming Method

In the case of using the positive resist material of the present invention for manufacturing various integrated circuits, known lithography technologies can be applied. Examples of the pattern forming method include a method which includes
(i) a step of forming a resist film by applying the above resist material onto a substrate to form a resist film;
(ii) a step of exposing the resist film to a high energy ray; and
(iii) a step of developing the exposed resist film with a developing solution.

### Step (i)

First, the positive resist material of the present invention is applied onto a substrate (Si, SiO₂, SiN, SiON, TiN, WSi, BPSG, SOG, an organic antireflection film, etc.) for manufacturing integrated circuits or a substrate (Cr, CrO, CrON, MoSi₂, SiO₂, etc.) for manufacturing mask circuits by an appropriate coating method such as spin coating, roll coating, dip coating, spray coating, and doctor coating so as to have the coating film thickness of 0.01 to 2 μm. This film is prebaked on a hotplate for 30 seconds to 20 minutes to form a resist film. In order to allow a crosslinking reaction by the crosslinking agent to proceed efficiently, the temperature of the prebaking is preferably 130° C. or more.

### Step (ii)

Then, the resist film is exposed using a high energy ray. Examples of the high energy ray include an ultraviolet ray, far ultraviolet ray, EB, EUV with a wavelength of 3 to 15 nm, X-ray, soft X-ray, excimer laser light, γ-ray, and synchrotron radiant ray. In the case of using the ultraviolet ray, far ultraviolet ray, EUV, X-ray, soft X-ray, excimer laser light, γ-ray, synchrotron radiant ray, and the like as the high energy ray, irradiation is performed directly or using a mask for forming an objective pattern such that the exposure amount is preferably about 1 to 200 mJ/cm², and more preferably about 10 to 100 mJ/cm². In the case of using EB as the high energy ray, drawing is performed directly or using a mask for forming an objective pattern with the exposure amount of preferably about 0.1 to 100 μC/cm², and more preferably about 0.5 to 50 μC/cm². The positive type resist material of the present invention is particularly suitable for fine patterning by KrF excimer laser light, ArF excimer laser light, EB, EUV, X-ray, soft X-ray, γ-ray, and synchrotron radiant ray, and more particularly suitable for fine patterning by EB or EUV among the high energy rays.

After the exposure, PEB (post-exposure baking) may be performed on a hot plate or in an oven, preferably at 50 to 150° C. for 10 seconds to 30 minutes, and more preferably at 60 to 120° C. for 30 seconds to 20 minutes. The PEB is a heating step performed after the exposure of the resist film.

Step (iii)

After the exposure or PEB, development of the exposed resist film is performed with conventional methods such as a dip method, puddle method, and spray method for 3 seconds to 3 minutes, and preferably 5 seconds to 2 minutes using a developing solution of an alkaline aqueous solution containing 0.1 to 10% by mass, and preferably 2 to 5% by mass of tetramethyl ammonium hydroxide (TMAH), tetraethyl ammonium hydroxide (TEAH), tetrapropyl ammonium hydroxide (TPAH), tetrabutyl ammonium hydroxide (TBAH), or the like. Thus, the part exposed to light is dissolved in the developing solution, and the part which is not exposed is not dissolved in the developing solution. Accordingly, the objective positive pattern is formed on the substrate.

The development can also be performed by organic solvent development using the above resist material. Examples of the developing solution to be used in this occasion include 2-octanone, 2-nonanone, 2-heptanone, 3-heptanone, 4-heptanone, 2-hexanone, 3-hexanone, diisobutyl ketone, methyl cyclohexanone, acetophenone, methyl acetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenyl propionate, benzyl propionate, ethyl phenyl acetate, and 2-phenylethyl acetate. These organic solvents can be used singly or in a combination of two or more kinds.

At the completion of the development, rinsing is performed. The rinsing solution is preferably a solvent which is mixed with and dissolved in the developing solution and does not dissolve the resist film. Preferable examples of such a solvent include alcohols having 3 to 10 carbon atoms, ether compounds having 8 to 12 carbon atoms, alkanes, alkenes, and alkynes having 6 to 12 carbon atoms, and aromatic solvents.

Specifically, examples of the alcohols having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol.

Examples of the ether compounds having 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether.

Examples of the alkanes having 6 to 12 carbon atoms include hexane, heptane, octane, nonane, decane, undecane, dodecane, methyl cyclopentane, dimethyl cyclopentane, cyclohexane, methyl cyclohexane, dimethyl cyclohexane, cycloheptane, cyclooctane, and cyclononane. Examples of the alkenes having 6 to 12 carbon atoms include hexene, heptene, octene, cyclohexene, methyl cyclohexene, dimethyl cyclohexene, cycloheptene, and cyclooctene. Examples of the alkynes having 6 to 12 carbon atoms include hexyne, heptyne, and octyne.

Examples of the aromatic solvents include toluene, xylene, ethylbenzene, isopropylbenzene, tert-butylbenzene, and mesitylene.

By performing rinsing, generation of collapse or defect of a resist pattern can be reduced. The rinsing is not mandatory, and it is possible to skip rinsing to reduce the amount of the solvent to be used.

Developed hole pattern or trench pattern can be shrunk by thermal flow, RELACS technology, or DSA technology. A shrink agent is applied on the hole pattern, and due to diffusion of an acid catalyst from the resist film during baking, crosslinking of the shrink agent occurs on the surface of the resist film, thereby the shrink agent is adhered to the side wall of the hole pattern. The baking temperature is preferably 70 to 180° C., and more preferably 80 to 170° C. The baking time is preferably 10 to 300 seconds to remove an unnecessary shrink agent, and the hole pattern in reduced.

### EXAMPLE

Hereinafter, the present invention will be specifically described with reference to Examples and Comparative Examples. However, the present invention is not limited thereto.

### Preparation of Resist Material and Evaluation Thereof

### (1) Preparation of Resist Material

Solutions obtained by dissolving the components according to the compositions shown in Tables 1 and 2 in solvents in which a surfactant PolyFox PF-636 manufactured by OMNOVA Solutions Inc. was dissolved at 50 ppm were filtered with 0.2 μm size filters to prepare resist materials (for Examples: R1 to R16, for Comparative Examples: cR1 to cR18). The content of the respective resist materials is shown in Tables 1 and 2.

The content of the components in Tables 1 and 2 are as follows.
Organic solvents: PGMEA (propylene glycol monomethyl ether acetate)
   DAA (diacetone alcohol)
   EL (Ethyl lactate)
Base polymer: P-1 to P-11, cP-1, cP-2

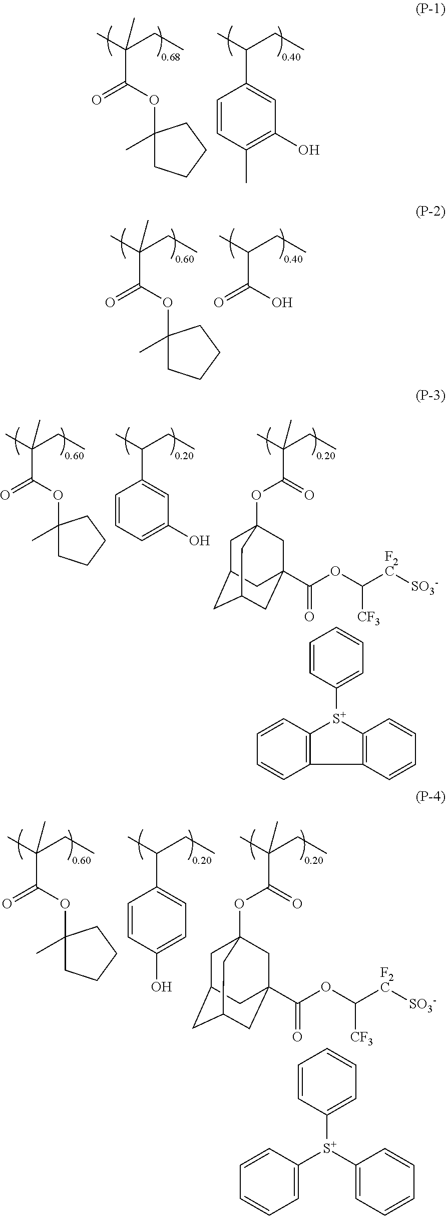

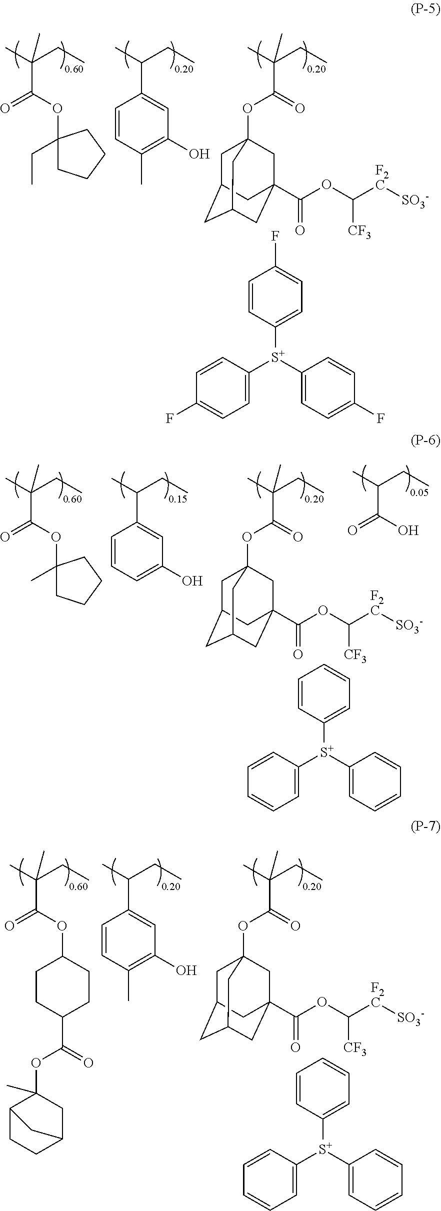

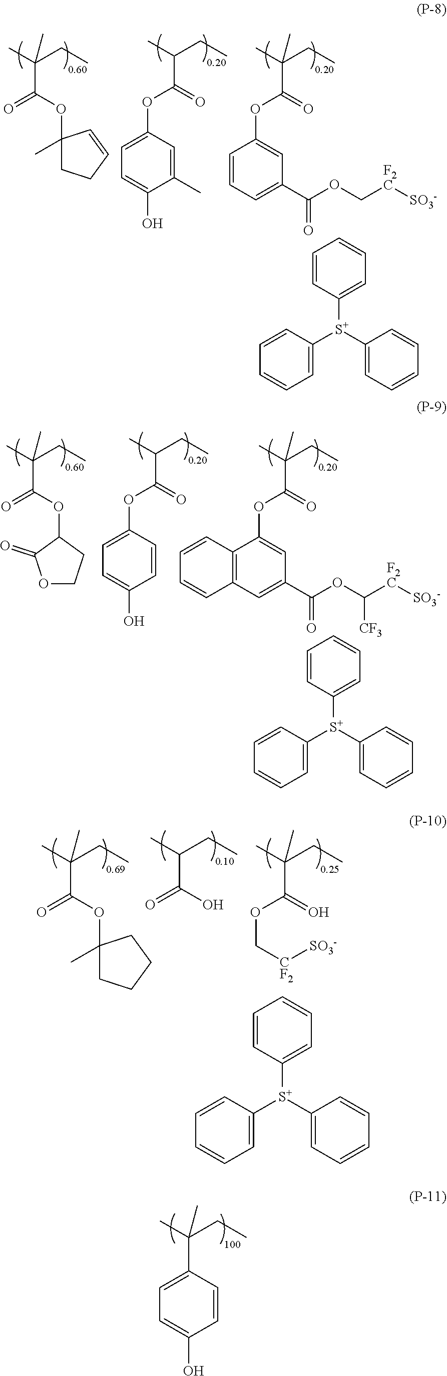

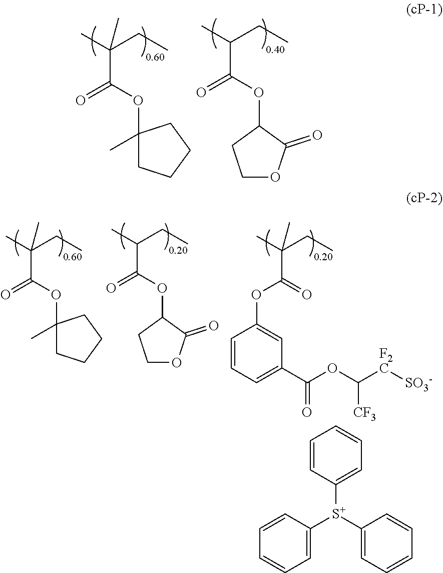

Photoacid generator: PAG-1 to PAG-4

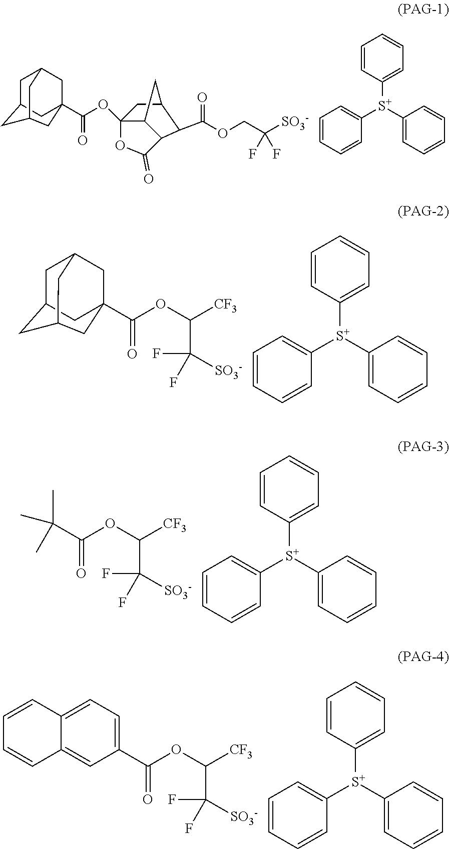

Quencher: Q-1 to Q-8, cQ-1 to cQ-9

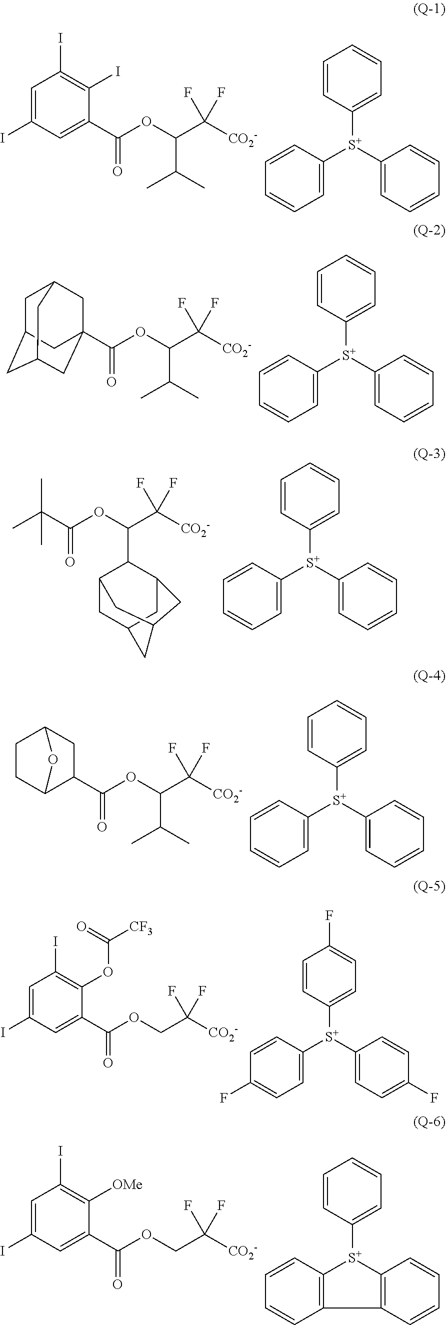

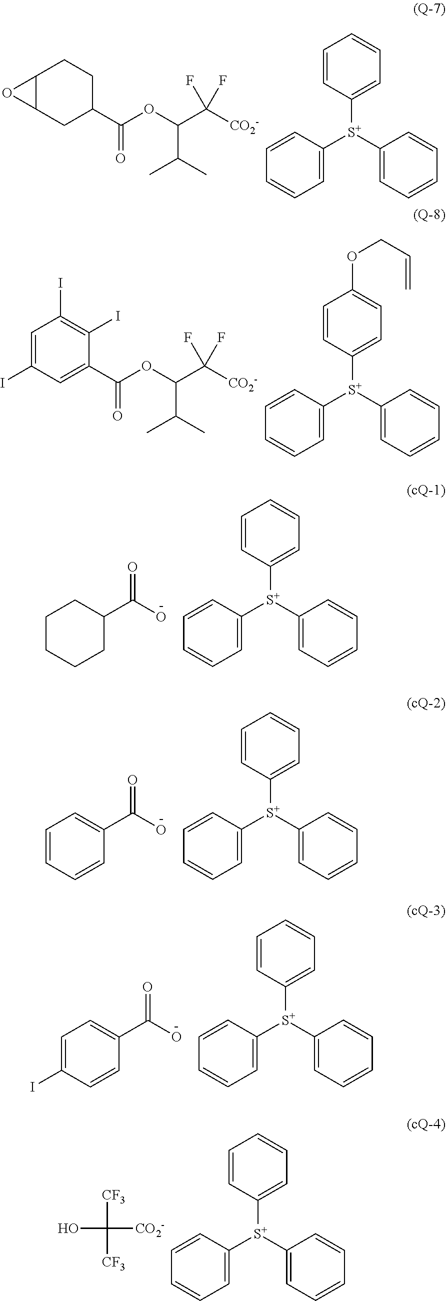

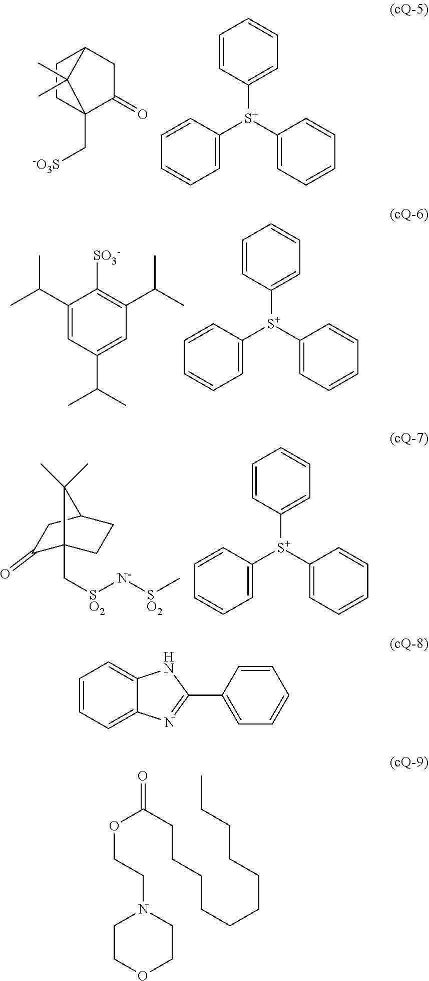

Crosslinking agent: X-1, X-2, X-3, X-4

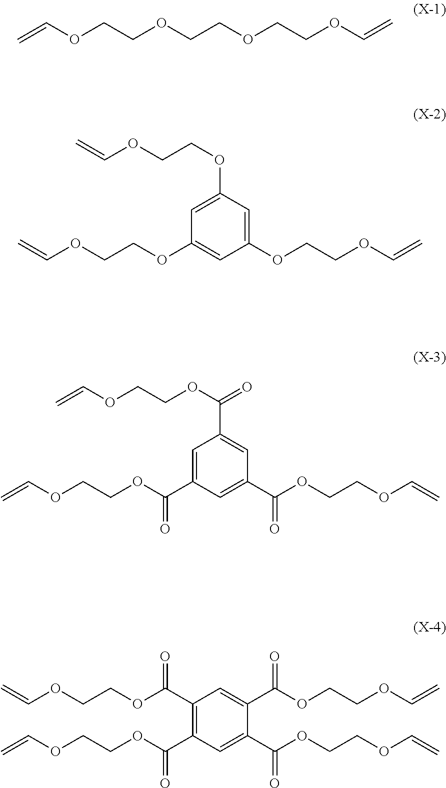

Thermal acid generator: T-1, T-2

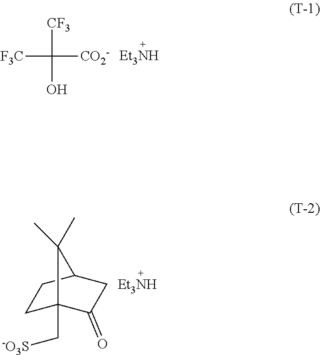

Other additive: A-1

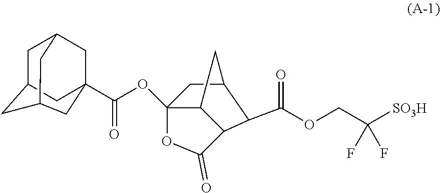 [SMILES: O=C(OCC(F)(F)S(=O)(=O)O)C1C2CC3C1C(=O)OC3(OC(=O)C13CC4CC(CC(C4)C1)C3)C2]

TABLE 1

| | | | | Cross- | | |
|---|---|---|---|---|---|---|
| | Base | Photoacid | Quencher | linking | Additive | |
| | polymer | generator | (number | agent | (number | |
| Resist | (number | (number of | of | (number | of parts | |
| com- | of parts | parts | parts | of parts | by | Organic |
| position | by mass) | by mass) | by mass) | by mass) | mass) | solvent |
| R1 | P-1 | PAG-1 | Q-1 | X-1 | — | PGMEA/ |
| | (80) | (5) | (14) | (13) | | DAA/EL |
| R2 | P-1 | PAG-2 | Q-2 | X-2 | — | PGMEA/ |
| | (80) | (5) | (14) | (13) | | DAA/EL |
| R3 | P-2 | PAG-3 | Q-3 | X-1 | — | PGMEA/ |
| | (80) | (6) | (14) | (13) | | DAA |
| R4 | P-2 | PAG-4 | Q-4 | X-2 | — | PGMEA/ |
| | (80) | (4) | (14) | (13) | | DAA |
| R5 | P-3 | PAG-1 | Q-5 | X-3 | — | PGMEA/ |
| | (80) | (5) | (14) | (13) | | DAA |
| R6 | P-4 | PAG-2 | Q-6 | X-4 | — | PGMEA/ |
| | (80) | (5) | (14) | (13) | | DAA |
| R7 | P-5 | — | Q-7 | X-2 | — | PGMEA/ |
| | (80) | | (14) | (13) | | EL |
| R8 | P-6 | — | Q-8 | X-3 | — | PGMEA/ |
| | (80) | | (14) | (13) | | EL |
| R9 | P-7 | — | Q-4 | X-2 | — | PGMEA/ |
| | (80) | | (14) | (13) | | EL |
| R10 | P-8 | — | Q-5 | X-3 | — | PGMEA/ |
| | (80) | | (14) | (13) | | EL |
| R11 | P-9 | — | Q-6 | X-4 | — | PGMEA/ |
| | (80) | | (14) | (13) | | EL |
| R12 | P-10 | — | Q-7 | X-2 | — | PGMEA/ |
| | (80) | | (14) | (13) | | EL |
| R13 | P-11 | PAG-1 | Q-8 | X-3 | — | PGMEA/ |
| | (80) | (5) | (14) | (13) | | EL |
| R14 | P-4 | — | Q-6 | X-4 | T-1 | PGMEA/ |
| | (80) | | (14) | (13) | (5) | DAA/EL |
| R15 | P-5 | — | Q-7 | X-2 | T-2 | PGMEA/ |
| | (80) | | (14) | (13) | (5) | DAA/EL |

TABLE 2

| | | | | Cross- | | |
|---|---|---|---|---|---|---|
| | Base | Photoacid | Quencher | linking | Additive | |
| | polymer | generator | (number | agent | (number | |
| Resist | (number | (number of | of | (number | of parts | |
| com- | of parts | parts | parts | of parts | by | Organic |
| position | by mass) | by mass) | by mass) | by mass) | mass) | solvent |
| cR1 | P-1 | — | Q-1 | X-2 | A-1 | PGMEA/ |
| | (80) | | (14) | (13) | (0.5) | DAA/EL |
| cR2 | P-2 | — | Q-1 | X-2 | A-1 | PGMEA/ |
| | (80) | | (14) | (13) | (0.5) | DAA/EL |
| cR3 | P-3 | PAG-1 | Q-5 | — | — | PGMEA/ |
| | (80) | (5) | (14) | | | DAA/EL |
| cR4 | c P-2 | PAG-2 | Q-1 | X-2 | — | PGMEA/ |
| | (80) | | (14) | (13) | | DAA/EL |
| cR5 | c P-1 | PAG-1 | Q-1 | X-3 | — | PGMEA/ |
| | (80) | | (14) | (13) | | DAA/EL |
| cR6 | c P-2 | PAG-2 | Q-1 | X-3 | — | PGMEA/ |
| | (80) | | (14) | (13) | | DAA/EL |
| cR7 | P-1 | PAG-3 | cQ-1 | X-2 | — | PGMEA/ |
| | (80) | | (14) | (13) | | DAA/EL |
| cR8 | P-2 | PAG-4 | cQ-2 | X-3 | — | PGMEA/ |
| | (80) | | (14) | (13) | | DAA/EL |
| cR9 | P-3 | — | cQ-3 | X-2 | — | PGMEA/ |
| | (80) | | (14) | (13) | | DAA/EL |
| cR10 | P-4 | — | cQ-4 | X-3 | — | PGMEA/ |
| | (80) | | (14) | (13) | | DAA/EL |
| cR11 | P-5 | — | cQ-5 | X-3 | — | PGMEA/ |
| | (80) | | (14) | (13) | | DAA/EL |
| cR12 | P-6 | — | cQ-6 | X-1 | — | PGMEA/ |
| | (80) | | (14) | (13) | | DAA/EL |
| cR13 | P-7 | — | cQ-7 | X-2 | — | PGMEA/ |
| | (80) | | (14) | (13) | | DAA/EL |
| cR14 | P-8 | — | cQ-8 | X-3 | — | PGMEA/ |
| | (80) | | (14) | (13) | | DAA/EL |
| cR15 | P-9 | — | cQ-9 | X-4 | — | PGMEA/ |
| | (80) | | (14) | (13) | | DAA/EL |

### (2) Evaluation of Crosslinking Reactivity (Examples 1-1 to 1-21, Comparative Examples 1-1 to 1-13)

The resist materials R1 to R15 and cR3 to cR15 were spin-coated on Si substrates and prebaked using a hot plate for 60 seconds to prepare resist films having a film thickness of 50 nm. These films were peeled off from the substrates, dissolved in organic solvents, and the weight average molecular weight in terms of polystyrene were measured by gel permeation chromatography (GPC) using dimethyl formamide as a solvent. In addition, the molecular weight was similarly measured for those obtained by performing overall exposure at 1.0 mJ to the resist films formed from R1 to R15 and cR3 to cR 15 using a KrF exposure apparatus (S206D; manufactured by Nikon Corporation), and then performing PEB for 60 seconds. Table 3 shows the temperature when performing the prebaking and PEB in producing the resist films of Examples 1-1 to 1-21, and the molecular weight after the prebaking and PEB. Table 4 shows the same contents as Table 3 for Comparative Examples 1-1 to 1-13.

### (3) Evaluation of Dissolution Contrast (Examples 2-1 to 2-20, Comparative Examples 2-1 to 2-13)

The resist materials R1 to R15, and cR3 to cR15 were spin-coated on DUV-42, an antireflective film manufactured by Nissan Chemical Corporation, prepared to have a film thickness of 61 nm on an 8-inch wafer, and prebaked using a hot plate for 60 seconds to prepare resist films having a film thickness of 50 nm. The obtained films were exposed using the KrF exposure apparatus (S206D; manufactured by Nikon Corporation), subjected to PEB on a hot plate at 95° C. for 60 seconds, and developed for 30 seconds. The films of Examples 2-1 to 2-19 were developed with a 2.38 mass % TMAH aqueous solution, and the film of Example 2-20 was developed with butyl acetate. The thickness of the resist films after the developing treatment was measured, the relation between the exposure amount and the resist film thickness after the developing treatment was plotted to analyze the dissolution contrast. Furthermore, the contrast was evaluated according to the following evaluation criteria, and shown as Examples 2-1 to 2-20 and Comparative Examples 2-1 to 2-13. For measurement of the film thickness, VM-2210, a film thickness meter manufactured by Hitachi High-Tech Corporation, was used. Table 5 shows the results of Examples 2-1 to 2-20, and Table 6 shows the results of Comparative Examples 2-1 to 2-13.

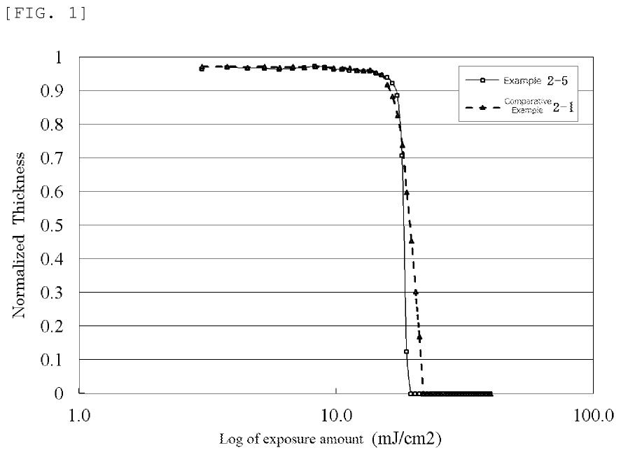

As representative compositions for evaluation of the dissolution contrast, the contrast curves of the resist films of Example 2-5 and Comparative Example 2-1 are shown in FIG. 1. The vertical axis in FIG. 1 shows values obtained by normalizing the film thickness after the developing treatment with the film thickness before the treatment. The contrast values in Table 5 show the inclination of the film thickness change relative to the exposure amount where the solubility of the resist film to the developing solution changes rapidly. In an interval from the point where the film thickness becomes 80% or less of the initial film thickness to the point where the film is completely dissolved, the inclination obtained by setting the horizontal axis as a log of exposure amount, and the vertical axis as a normalized film thickness, is regard as a contrast value. The contrast of the resist films formed from the respective resist compositions was evaluated as follows based on the absolute value of the contrast value.

### (Evaluation Criteria)

Excellent: The absolute value of the contrast value is 10 or more
Good: The absolute value of the contrast value is 5 or more and less than 10
Poor: The absolute value of the contrast value is less than 5

### (4) Evaluation of Storage Stability (Examples 3-1 to 3-15, Comparative Examples 3-1 and 3-2)

The resist materials listed in Tables 1 and 2 were stored at 40° C. and 23° C. for two weeks, and then spin-coated on DUV-42, an antireflective film manufactured by Nissan Chemical Corporation, prepared to have a film thickness of 61 nm on an 8-inch wafer, and prebaked using a hot plate for 60 seconds to prepare resist films having a film thickness of about 50 nm. For measurement of the film thickness, VM-2210, a film thickness meter manufactured by Hitachi High-Tech Corporation, was used. The difference of the film thickness for the resist materials stored at 40° C. and 23° C. was evaluated under the same conditions according to the following evaluation criteria. Table 7 shows the results of Examples 3-1 to 3-15, and Table 8 shows the results of Comparative Examples 3-1 and 3-2.

### (Evaluation Criteria)

Good: Difference of film thickness is less than 5 Å
Poor: Difference of film thickness is 5 Å or more

### (5) Evaluation of Lithography (Examples 4-1 to 4-15, Comparative Examples 4-1 to 4-13)

The resist materials R1 to R15 and cR3 to cR15 listed in Tables 1 and 2 were spin-coated on DUV-42, an antireflective film manufactured by Nissan Chemical Corporation, prepared to have a film thickness of 61 nm on an 8-inch wafer, and prebaked using a hot plate for 60 seconds to prepare resist films having a film thickness of about 50 nm. The obtained films were exposed using an electron beam drawing apparatus manufactured by Elionix Inc. (ELS-F125, acceleration voltage 125 kV), subjected to PEB at 95° C. for 60 seconds on a hot plate, and developed with the 2.38 mass % TMAH aqueous solution for 30 seconds. The developed patterns were observed with a length measuring SEM (S9380) manufactured by Hitachi High-Tech Corporation. The standard deviation (σ) calculated from the results was tripled, and the obtained value (3σ) was determined as variation of pattern width (LWR). Furthermore, the variation of pattern width was evaluated based on the following evaluation criteria. Table 9 shows the results of Examples 4-1 to 4-15, and Table 10 shows the results of Comparative Examples 4-1 to 4-13.

### (Evaluation Criteria)

Excellent: The value of LWR is less than 3.0
Good: The value of LWR is 3.0 or more and less than 4.0
Poor: The value of LWR is 4.0 or more

TABLE 3

| | | Prebaking | PEB | Molecular | Molecular |
|---|---|---|---|---|---|
| | Resist | temperature | temperature | weight | weight |
| Examples | composition | (° C.) | (° C.) | after prebaking | after PEB |
| Example 1-1 | R1 | 130 | 95 | 1.1 × 10⁴ | 2.0 × 10⁴ |
| Example 1-2 | R2 | 130 | 95 | 1.3 × 10⁴ | 2.3 × 10⁴ |
| Example 1-3 | R3 | 130 | 95 | 1.1 × 10⁴ | 2.2 × 10⁴ |
| Example 1-4 | R4 | 130 | 95 | 1.2 × 10⁴ | 2.1 × 10⁴ |
| Example 1-5 | R5 | 130 | 95 | 1.1 × 10⁴ | 2.3 × 10⁴ |
| Example 1-6 | R5 | 150 | 95 | 1.7 × 10⁴ | 2.3 × 10⁴ |
| Example 1-7 | R5 | 160 | 95 | 1.3 × 10⁴ | 2.3 × 10⁴ |
| Example 1-8 | R6 | 130 | 95 | 1.1 × 10⁴ | 2.4 × 10⁴ |
| Example 1-9 | R6 | 150 | 95 | 1.8 × 10⁴ | 2.4 × 10⁴ |
| Example 1-10 | R6 | 160 | 95 | 1.4 × 10⁴ | 2.4 × 10⁴ |
| Example 1-11 | R7 | 130 | 95 | 1.2 × 10⁴ | 2.4 × 10⁴ |
| Example 1-12 | R8 | 130 | 95 | 1.4 × 10⁴ | 2.5 × 10⁴ |
| Example 1-13 | R9 | 130 | 95 | 1.2 × 10⁴ | 2.4 × 10⁴ |
| Example 1-14 | R10 | 130 | 95 | 1.4 × 10⁴ | 2.5 × 10⁴ |
| Example 1-15 | R11 | 130 | 95 | 1.4 × 10⁴ | 2.6 × 10⁴ |
| Example 1-16 | R12 | 130 | 95 | 1.2 × 10⁴ | 2.4 × 10⁴ |
| Example 1-17 | R13 | 130 | 95 | 1.4 × 10⁴ | 2.5 × 10⁴ |
| Example 1-18 | R14 | 130 | 95 | 1.0 × 10⁵ | insoluble |
| Example 1-19 | R15 | 130 | 95 | 1.0 × 10⁵ | 1.5 × 10⁵ |
| Example 1-20 | R5 | 100 | 95 | 7.6 × 10³ | 1.5 × 10⁴ |
| Example 1-21 | R5 | 115 | 95 | 8.0 × 10³ | 1.7 × 10⁴ |

TABLE 4

| | | Prebaking | PEB | Molecular | Molecular |
|---|---|---|---|---|---|
| Comparative | Resist | temperature | temperature | weight | weight |
| Examples | composition | (° C.) | (° C.) | after prebaking | after PEB |
| Comp. Ex. 1-1 | cR3 | 130 | 95 | 8.0 × 10³ | 7.9 × 10³ |
| Comp. Ex. 1-2 | cR4 | 130 | 95 | 8.1 × 10³ | 8.0 × 10³ |
| Comp. Ex. 1-3 | cR5 | 130 | 95 | 8.0 × 10³ | 7.9 × 10³ |
| Comp. Ex. 1-4 | cR6 | 130 | 95 | 8.0 × 10³ | 8.0 × 10³ |
| Comp. Ex. 1-5 | cR7 | 130 | 95 | 1.3 × 10⁴ | 1.3 × 10⁴ |
| Comp. Ex. 1-6 | cR8 | 130 | 95 | 1.1 × 10⁴ | 1.1 × 10⁴ |
| Comp. Ex. 1-7 | cR9 | 130 | 95 | 1.4 × 10⁴ | 9.5 × 10³ |
| Comp. Ex. 1-8 | cR10 | 130 | 95 | 1.1 × 10⁴ | 9.1 × 10³ |
| Comp. Ex. 1-9 | cR11 | 130 | 95 | 1.3 × 10⁴ | 8.5 × 10³ |
| Comp. Ex. 1-10 | cR12 | 130 | 95 | 1.1 × 10⁴ | 7.9 × 10³ |
| Comp. Ex. 1-11 | cR13 | 130 | 95 | 1.4 × 10⁴ | 8.1 × 10³ |
| Comp. Ex. 1-12 | cR14 | 130 | 95 | 8.1 × 10³ | 8.1 × 10³ |
| Comp. Ex. 1-13 | cR15 | 130 | 95 | 8.1 × 10³ | 8.1 × 10³ |

TABLE 5

| | | Prebaking | | Evaluation |
|---|---|---|---|---|
| | Resist | temperature | | of |
| Examples | composition | (° C.) | Contrast | contrast |
| Example 2-1 | R1 | 130 | −5.2 | good |
| Example 2-2 | R2 | 130 | −5.7 | good |
| Example 2-3 | R3 | 130 | −5.8 | good |
| Example 2-4 | R4 | 130 | −5.9 | good |
| Example 2-5 | R5 | 130 | −13.7 | excellent |
| Example 2-6 | R5 | 150 | −14.2 | excellent |
| Example 2-7 | R5 | 160 | −14.1 | excellent |
| Example 2-8 | R6 | 130 | −14.3 | excellent |
| Example 2-9 | R6 | 150 | −14.7 | excellent |
| Example 2-10 | R6 | 160 | −14.6 | excellent |
| Example 2-11 | R7 | 130 | −11.6 | excellent |
| Example 2-12 | R8 | 130 | −13.9 | excellent |
| Example 2-13 | R9 | 130 | −11.4 | excellent |
| Example 2-14 | R10 | 130 | −11.9 | excellent |
| Example 2-15 | R11 | 130 | −7.0 | good |
| Example 2-16 | R12 | 130 | −10.5 | excellent |
| Example 2-17 | R13 | 130 | −5.5 | good |
| Example 2-18 | R14 | 130 | −14.4 | excellent |
| Example 2-19 | R15 | 130 | −14.7 | excellent |
| Example 2-20 | R5 | 130 | −5.6 | good |

TABLE 6

| | | Prebaking | | Evaluation |
|---|---|---|---|---|
| Comparative | Resist | temperature | | of |
| Examples | composition | (° C.) | Contrast | contrast |
| Comp. Ex. 2-1 | cR3 | 130 | −2.0 | poor |
| Comp. Ex. 2-2 | cR4 | 130 | −2.5 | poor |
| Comp. Ex. 2-3 | cR5 | 130 | −2.2 | poor |
| Comp. Ex. 2-4 | cR6 | 130 | −2.3 | poor |
| Comp. Ex. 2-5 | cR7 | 130 | −2.9 | poor |
| Comp. Ex. 2-6 | cR8 | 130 | −3.0 | poor |
| Comp. Ex. 2-7 | cR9 | 130 | −3.3 | poor |
| Comp. Ex. 2-8 | cR10 | 130 | −3.4 | poor |
| Comp. Ex. 2-9 | cR11 | 130 | −3.2 | poor |
| Comp. Ex. 2-10 | cR12 | 130 | −3.4 | poor |
| Comp. Ex. 2-11 | cR13 | 130 | −3.3 | poor |
| Comp. Ex. 2-12 | cR14 | 130 | −3.4 | poor |
| Comp. Ex. 2-13 | cR15 | 130 | −3.4 | poor |

TABLE 7

| | Resist | Film thickness | |
|---|---|---|---|
| Examples | composition | (Å ) | Evaluation |
| Example 3-1 | R1 | 0.7 | good |
| Example 3-2 | R2 | 0.5 | good |
| Example 3-3 | R3 | 0.5 | good |
| Example 3-4 | R4 | 0.7 | good |
| Example 3-5 | R5 | 1.0 | good |
| Example 3-6 | R6 | 0.9 | good |
| Example 3-7 | R7 | 1.1 | good |
| Example 3-8 | R8 | 1.3 | good |
| Example 3-9 | R9 | 0.8 | good |
| Example 3-10 | R10 | 0.8 | good |
| Example 3-11 | R11 | 0.5 | good |
| Example 3-12 | R12 | 0.6 | good |
| Example 3-13 | R13 | 0.2 | good |
| Example 3-14 | R14 | 3.5 | good |
| Example 3-15 | R15 | 3.3 | good |

TABLE 8

| | | Film | |
|---|---|---|---|
| Comparative | Resist | thickness | |
| Examples | composition | (Å ) | Evaluation |
| Comparative | cR1 | 10.6 | poor |
| Example 3-1 | | | |
| Comparative | cR2 | 11.1 | poor |
| Example 3-2 | | | |

TABLE 9

| Examples | Resist composition | LWR | Evaluation |
|---|---|---|---|
| Example 4-1 | R1 | 3.52 | good |
| Example 4-2 | R2 | 3.39 | good |
| Example 4-3 | R3 | 3.42 | good |
| Example 4-4 | R4 | 3.51 | good |
| Example 4-5 | R5 | 2.98 | excellent |
| Example 4-6 | R6 | 2.77 | excellent |
| Example 4-7 | R7 | 2.73 | excellent |
| Example 4-8 | R8 | 2.62 | excellent |
| Example 4-9 | R9 | 2.51 | excellent |
| Example 4-10 | R10 | 2.48 | excellent |
| Example 4-11 | R11 | 2.45 | excellent |
| Example 4-12 | R12 | 2.52 | excellent |
| Example 4-13 | R13 | 3.79 | good |
| Example 4-14 | R14 | 2.66 | excellent |
| Example 4-15 | R15 | 2.58 | excellent |

TABLE 10

| Comparative | Resist | | |
|---|---|---|---|
| Examples | composition | LWR | Evaluation |
| Comparative | cR3 | 4.52 | poor |
| Example | | | |
| 4-1 | | | |
| Comparative | cR4 | 4.54 | poor |
| Example | | | |
| 4-2 | | | |
| Comparative | cR5 | 4.46 | poor |
| Example | | | |
| 4-3 | | | |
| Comparative | cR6 | 4.34 | poor |
| Example | | | |
| 4-4 | | | |
| Comparative | cR7 | 4.11 | poor |
| Example | | | |
| 4-5 | | | |
| Comparative | cR8 | 4.41 | poor |
| Example | | | |
| 4-6 | | | |
| Comparative | cR9 | 4.23 | poor |
| Example | | | |
| 4-7 | | | |
| Comparative | cR10 | 4.19 | poor |
| Example | | | |
| 4-8 | | | |
| Comparative | cR11 | 4.83 | poor |
| Example | | | |
| 4-9 | | | |
| Comparative | cR12 | 4.77 | poor |
| Example | | | |
| 4-10 | | | |
| Comparative | cR13 | 4.68 | poor |
| Example | | | |
| 4-11 | | | |
| Comparative | cR14 | 4.57 | poor |
| Example | | | |
| 4-12 | | | |
| Comparative | cR15 | 4.65 | poor |
| Example | | | |
| 4-13 | | | |

In Examples 1-1 to 1-21, in which a vinyl ether crosslinking agent is contained, it was suggested that the average molecular weight increased after prebaking and a crosslinking reaction proceeded as shown in Tables 3 and 4. In addition, further increase in the molecular weight was observed after minute exposure and PEB, and it was confirmed that a crosslinking reaction proceeded due to weak acids derived from the quenchers (Q-1 to Q-8) functioning as catalysts. In Example 1-18, it was found that crosslinking proceeded such that the resist film after minute exposure and PEB was insoluble in a GPC solvent. On the other hand, in the resist containing a carboxylate type quencher or a nitrogen quencher, increase in the molecular weight after minute exposure and PEB was not observed. Meanwhile, in the resist containing a sulfonate type quencher, the molecular weight after minute exposure and PEB was lower than the molecular weight after prebaking. This is because an acetal crosslinking structure formed in the prebaking step is decomposed by a sulfonic acid. It was revealed that the acidity of the quencher is important for promoting a crosslinking reaction.

As shown in FIG. 1, it was confirmed that a solubility difference between the exposed part and unexposed part in Example 2-5 is significantly greater than in Comparative Example 2-1, and the film thickness change after the developing treatment relative to the exposure amount was steep. The values of contrast in Tables 5 and 6 show the inclination of this film thickness change, and the greater the absolute value, the superior the dissolution contrast. Any of Examples 2-1 to 2-20 in which a polymer having a reactive group, a crosslinking agent, and a fluorocarboxylate type quencher are contained showed preferable contrast. This is supposedly because an acid derived from the quencher generated in the minute exposed part promotes a crosslinking reaction. Further, it was made clear that the resist composition having a structural unit (C) which generates an acid by light in a base polymer shows especially excellent contrast. Since the structural unit (C) is high in polarity and hydrophilicity, an uncrosslinked low molecular weight compound containing (C) has high solubility to a developing solution. On the other hand, when the molecular weight of such a readily-soluble component is increased by crosslinking, the solubility to a developing solution significantly decreases. By this effect, the dissolution contrast between the exposed part and unexposed part can be greatly changed, and therefore the base polymer preferably contains the structural unit (C).

In the resist films prepared by using the resist compositions cR1 and cR2, which contain a trace amount of an acid A-1 as a crosslinking promoter without containing a photoacid generator, the film thickness significantly increased during long-term storage as shown in Comparative Examples 3-1 and 3-2 in Table 8. Since the acid A-1 is contained in Comparative Examples 3-1 and 3-2 as a crosslinking promoter, this change is supposedly caused by progress of a crosslinking reaction during storage as a solution to increase the molecular weight of the polymer. Therefore, it was shown that the resist material containing neither the structural unit (C) nor a photoacid generator is inferior in storage stability.

Any of Examples 4-1 to 4-15 in which a polymer having a reactive group, a crosslinking agent, and a fluorocarboxylate type quencher are contained showed preferable LWR. In addition, the resist composition containing the structural unit (C) which generates an acid by light in a base polymer showed particularly excellent LWR.

The above results show that the resist material of the present invention satisfies high dissolution contrast and preferable LEW, and therefore is a resist material with which the edge roughness and dimension variation become small, superior resolution can be obtained, pattern shape becomes preferable after exposure, and further preferable storage stability can be obtained.

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1. A resist material comprising:
(Ia) a polymer containing a repeating unit (A) including a hydroxyl group or a carboxy group;
(II) a crosslinking agent having a structure represented by the following formula (1);
(III) a quencher having a structure represented by the following formula (2);
(IV) an organic solvent; and
(V) a component which is decomposed by irradiation of an active ray or a radiant ray to generate an acid, 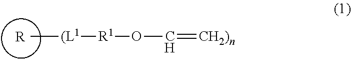
wherein R represents an n-valent organic group which may have a substituent; L¹ represents a linking group selected from a single bond, an ester bond, and an ether bond; R¹ represents a single bond or a divalent organic group; and n is an integer of 1 to 4, 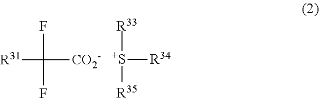
wherein R³¹ represents a monovalent organic group which may have a substituent; R³³ to R³⁵ each independently represent a monovalent hydrocarbon group which has 1 to 20 carbon atoms and may contain a hetero atom; and either two of R³³, R³⁴, and R³⁵ may bond to each other to form a ring with the sulfur atom to which they bond.

2. A resist material comprising:
(Ib) a polymer containing a repeating unit (A) including a hydroxyl group or a carboxy group, and a repeating unit (C) having a structural site which is decomposed by irradiation of an active ray or a radiant ray to generate an acid;
(II) a crosslinking agent having a structure represented by the following formula (1);
(III) a quencher having a structure represented by the following formula (2); and
(IV) an organic solvent, 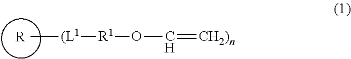
wherein R represents an n-valent organic group which may have a substituent; L¹ represents a linking group selected from a single bond, an ester bond, and an ether bond; R¹ represents a single bond or a divalent organic group; and n is an integer of 1 to 4, 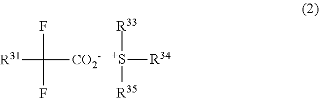
wherein R³¹ represents a monovalent organic group which may have a substituent; R³³ to R³⁵ each independently represent a monovalent hydrocarbon group which has 1 to 20 carbon atoms and may contain a hetero atom; and
either two of R³³, R³⁴, and R³⁵ may bond to each other to form a ring with the sulfur atom to which they bond.

3. The resist material according to claim 2, wherein the repeating unit (C) contained in the polymer is represented by the following formula (c), 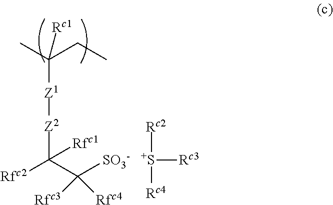
wherein R^{c1} represents a hydrogen atom or a methyl group; Z¹ represents a single bond or an ester bond; Z² represents a single bond or a divalent organic group having 1 to 25 carbon atoms, and may include one or more of an ester bond, an ether bond, a lactone ring, an amide bond, a sultone ring, and an iodine atom; Rf^{c1} to Rf^{c4} each independently represent a hydrogen atom, fluorine atom, or a trifluoromethyl group, and at least one of Rf^{c1} to Rf^{c4} is a fluorine atom or a trifluoromethyl group; and R^{c2} to R^{c4} each independently represent a monovalent hydrocarbon group which has 1 to 20 carbon atoms and may contain a hetero atom; and either two of R^{c2}, R^{c3}, and R^{c4} may bond to each other to form a ring with the sulfur atom to which they bond.

4. The resist material according to claim 2, further comprising (V) a component which is decomposed by irradiation of an active ray or a radiant ray to generate an acid.

5. The resist material according to claim 3, further comprising (V) a component which is decomposed by irradiation of an active ray or a radiant ray to generate an acid.

6. The resist material according to claim 1, wherein the repeating unit (A) contained in the polymer is represented by the following formula (a1) and/or (a2), 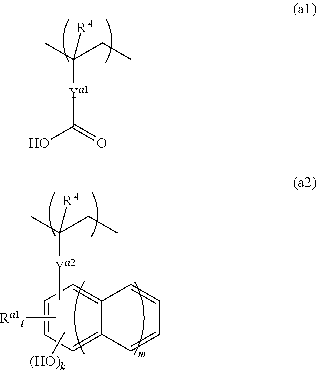
wherein R^{A}s each independently represent a hydrogen atom or a methyl group; Y^{a1} each independently represents a single bond, or a divalent linking group having 1 to 15 carbon atoms and including at least one or more of a phenylene group, a naphthylene group, an ester bond, an ether bond, a lactone ring, an amide group, and a hetero atom; Y^{a2} each independently represents a single bond, or a divalent linking group having 1 to 12 carbon atoms and including at least one or more of a phenylene group, a naphthylene group, an ester bond, an ether bond, a lactone ring, an amide group, and a hetero atom; R^{a1} represents a hydrogen atom, a fluorine atom, or an alkyl group; R^{a1} and Y^{a2} may bond to each other to form a ring; and k is an integer of 1 or 2, l is an integer of 0 to 4, and l≤k+1≤5; and m is 0 or 1.

7. The resist material according to claim 2, wherein the repeating unit (A) contained in the polymer is represented by the following formula (a1) and/or (a2), 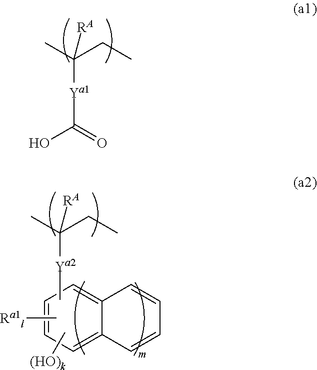
wherein R^{A}s each independently represent a hydrogen atom or a methyl group; Y^{a1} each independently represents a single bond, or a divalent linking group having 1 to 15 carbon atoms and including at least one or more of a phenylene group, a naphthylene group, an ester bond, an ether bond, a lactone ring, an amide group, and a hetero atom; Y^{a2} each independently represents a single bond, or a divalent linking group having 1 to 12 carbon atoms and including at least one or more of a phenylene group, a naphthylene group, an ester bond, an ether bond, a lactone ring, an amide group, and a hetero atom; R^{a1} represents a hydrogen atom, a fluorine atom, or an alkyl group; R^{a1} and Y^{a2} may bond to each other to form a ring; and k is an integer of 1 or 2, l is an integer of 0 to 4, and l≤k+1≤5; and m is 0 or 1.

8. The resist material according to claim 3, wherein the repeating unit (A) contained in the polymer is represented by the following formula (a1) and/or (a2), 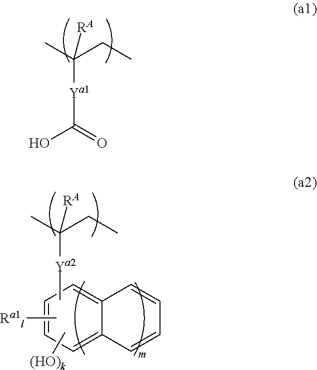
wherein R^{A}s each independently represent a hydrogen atom or a methyl group; Y^{a1} each independently represents a single bond, or a divalent linking group having 1 to 15 carbon atoms and including at least one or more of a phenylene group, a naphthylene group, an ester bond, an ether bond, a lactone ring, an amide group, and a hetero atom; Y^{a2} each independently represents a single bond, or a divalent linking group having 1 to 12 carbon atoms and including at least one or more of a phenylene group, a naphthylene group, an ester bond, an ether bond, a lactone ring, an amide group, and a hetero atom; R^{a1} represents a hydrogen atom, a fluorine atom, or an alkyl group; R^{a1} and Y^{a2} may bond to each other to form a ring; and k is an integer of 1 or 2, l is an integer of 0 to 4, and l≤k+1≤5; and m is 0 or 1.

9. The resist material according to claim 4, wherein the repeating unit (A) contained in the polymer is represented by the following formula (a1) and/or (a2), 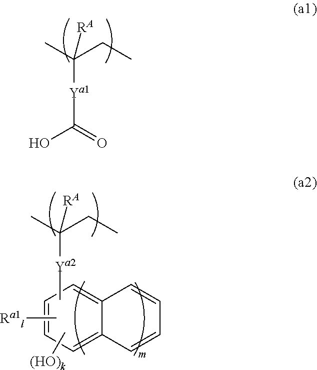
wherein R^{A}s each independently represent a hydrogen atom or a methyl group; Y^{a1} each independently represents a single bond, or a divalent linking group having 1 to 15 carbon atoms and including at least one or more of a phenylene group, a naphthylene group, an ester bond, an ether bond, a lactone ring, an amide group, and a hetero atom; Y^{a2} each independently represents a single bond, or a divalent linking group having 1 to 12 carbon atoms and including at least one or more of a phenylene group, a naphthylene group, an ester bond, an ether bond, a lactone ring, an amide group, and a hetero atom; R^{a1} represents a hydrogen atom, a fluorine atom, or an alkyl group; R^{a1} and Y^{a2} may bond to each other to form a ring; and k is an integer of 1 or 2, l is an integer of 0 to 4, and l≤k+1≤5; and m is 0 or 1.

10. The resist material according to claim 5, wherein the repeating unit (A) contained in the polymer is represented by the following formula (a1) and/or (a2), 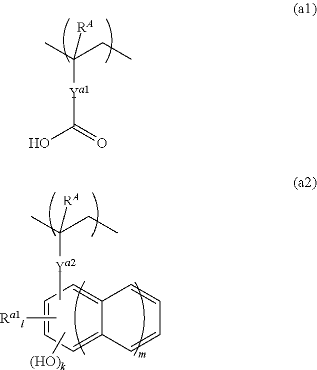
wherein R^{A}s each independently represent a hydrogen atom or a methyl group; Y^{a1} each independently represents a single bond, or a divalent linking group having 1 to 15 carbon atoms and including at least one or more of a phenylene group, a naphthylene group, an ester bond, an ether bond, a lactone ring, an amide group, and a hetero atom; Y^{a2} each independently represents a single bond, or a divalent linking group having 1 to 12 carbon atoms and including at least one or more of a phenylene group, a naphthylene group, an ester bond, an ether bond, a lactone ring, an amide group, and a hetero atom; R^{a1} represents a hydrogen atom, a fluorine atom, or an alkyl group; R^{a1} and Y^{a2} may bond to each other to form a ring; and k is an integer of 1 or 2, l is an integer of 0 to 4, and l≤k+1≤5; and m is 0 or 1.

11. The resist material according to claim 1, wherein R³¹ in the formula (2) comprises an iodine atom.

12. The resist material according to claim 2, wherein R³¹ in the formula (2) comprises an iodine atom.

13. The resist material according to claim 3, wherein R³¹ in the formula (2) comprises an iodine atom.

14. The resist material according to claim 4, wherein R³¹ in the formula (2) comprises an iodine atom.

15. The resist material according to claim 5, wherein R³¹ in the formula (2) comprises an iodine atom.

16. The resist material according to claim 1, wherein R in the formula (1) comprises an aromatic hydrocarbon group.

17. The resist material according to claim 2, wherein R in the formula (1) comprises an aromatic hydrocarbon group.

18. The resist material according to claim 3, wherein R in the formula (1) comprises an aromatic hydrocarbon group.

19. A pattern forming method which comprises
(i) a step of forming a resist film by applying the resist material according to claim 1 onto a substrate to form a resist film;
(ii) a step of exposing the resist film to a high energy ray; and
(iii) a step of developing the exposed resist film with a developing solution.

20. The pattern forming method according to claim 19, further comprising a step of prebaking the resist film at 130° C. or more in the step (i).
